(19) United States
(12) Patent Application Publication
(10) Pub. No.: US 2026/0032987 A1
(43) Pub. Date: Jan. 29, 2026

(54) GATE ISOLATION STRUCTURES

(71) Applicant: Taiwan Semiconductor Manufacturing Company, Ltd., Hsin-Chu (TW)

(72) Inventors: Ping-En Cheng, Hsinchu (TW); Chih-Hsuan Chen, Hsinchu (TW); Ping-Wei Wang, Hsinchu (TW); Jui-Lin Chen, Hsinchu (TW)

(21) Appl. No.: 18/981,129

(22) Filed: Dec. 13, 2024

Related U.S. Application Data
(60) Provisional application No. 63/675,834, filed on Jul. 26, 2024.

(51) Int. Cl. H10D 84/01; H10B 10/00; H10D 30/00; H10D 30/01; H10D 30/67; H10D 62/10; H10D 84/83

(52) U.S. Cl. CPC H10D 84/0153; H10B 10/125; H10D 30/0191; H10D 30/502; H10D 30/6735; H10D 62/121; H10D 84/832

(57) ABSTRACT

An IC structure and a method of forming the same are provided. In an embodiment, an exemplary method of forming the IC structure forming a high-k metal gate structure extending lengthwise along a first direction, forming a trench to separate the high-k metal gate structure into two portions, conformally depositing a first dielectric layer to substantially fill the trench, after the conformally depositing of the first dielectric layer, forming a patterned mask over the high-k metal gate structure, the patterned mask comprising an opening disposed directly over the trench, etching back the first dielectric layer while using the patterned mask as an etch mask to obtain a thinned first dielectric layer, and after the etching of the first dielectric layer, forming a second dielectric layer in the trench and on the thinned first dielectric layer.

### PRIORITY

This application claims the priority of U.S. Provisional Application Ser. No. 63/675,834, filed Jul. 26, 2024, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs and, for these advances to be realized, similar developments in IC processing and manufacturing are needed. For example, various methods have been developed to cut (or separate) metal gate structures in forming advanced ICs. While they have been generally adequate in providing isolation for metal gate structures, they have not been satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A is a diagrammatic plan view of an IC structure, in portion or entirety, according to various aspects of the present disclosure.

FIGS. 1B and 1C are diagrammatic plan views of an array of memory cells, such as static random-access memory (SRAM) cells, in portion or entirety, according to various aspects of the present disclosure.

FIG. 2 is a circuit diagram of a memory cell, such as an SRAM cell, that can be implemented in the IC structure of FIG. 1, according to various aspects of the present disclosure.

FIG. 3 is a fragmentary top, plan view of an intermediate structure of the IC structure including the array of memory cells and an array of logic cells, according to various aspects of the present disclosure.

FIG. 4 illustrates a flowchart of an exemplary method for fabricating gate isolation structures of the IC structure, according to various embodiments of the present disclosure.

FIGS. 5A, 6A, 7A, 8A, 9A, 10A, 11A, 12A, 13A, 14A, 15A illustrate fragmentary cross-sectional views of the IC structure taken along line A-A as shown in FIG. 3 during various fabrication stages in the method of FIG. 4, according to various embodiments of the present disclosure.

FIGS. 5B, 6B, 7B, 8B, 9B, 10B, 11B, 12B, 13B, 14B, 15B illustrate fragmentary cross-sectional views of the IC structure taken along line B-B as shown in FIG. 3 during various fabrication stages in the method of FIG. 4, according to various embodiments of the present disclosure.

FIGS. 5C, 6C, 7C, 8C, 9C, 10C, 11C, 12C, 13C, 14C, 15C illustrate fragmentary cross-sectional views of the IC structure taken along line C-C as shown in FIG. 3 during various fabrication stages in the method of FIG. 4, according to various embodiments of the present disclosure.

FIGS. 5D, 6D, 7D, 8D, 9D, 10D, 11D, 12D, 13D, 14D, 15D illustrate fragmentary cross-sectional views of the IC structure taken along line D-D as shown in FIG. 3 during various fabrication stages in the method of FIG. 4, according to various embodiments of the present disclosure.

FIG. 5E illustrates a fragmentary cross-sectional view of the IC structure taken along line E-E as shown in FIG. 3.

FIG. 16 is a fragmentary top, plan view of the IC structure including first gate isolation structures in the array of memory cells and second gate isolation structures in the array of logic cells, according to various aspects of the present disclosure.

FIGS. 17, 18, 19 illustrate fragmentary cross-sectional views of alternative first gate isolation structures in the IC structure, according to various aspects of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for case of the present disclosure of one features relationship to another feature. The spatially relative terms are intended to cover different orientations of the device including the features.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

Multi-gate devices, such as fin field-effect transistors (FinFETs) and gate-all-around (GAA) transistors, have been introduced in an effort to improve gate control by increasing gate-channel coupling, reduce OFF-state current, and reduce short-channel effects (SCEs). A FinFET has an elevated channel wrapped by a gate on more than one side (for example, the gate wraps a top and sidewalls of a “fin” of semiconductor material extending from a substrate). A GAA transistor has a gate structure that can extend, partially or fully, around a channel region to provide access to the channel region on two or more sides. The channel region of a GAA transistor may be formed from nanowires, nanosheets, or other nanostructures and for that reasons, a GAA transistor may also be referred to as a nanowire transistor or a nanosheet transistor. The three-dimensional structure of the multi-gate devices allows them to be aggressively scaled while maintaining gate control and mitigating SCEs.

Replacing polysilicon gates with high-k metal gate (HKMG) structures has brought about improvement in device performance as feature sizes continue to decrease. Generally, after a HKMG structure is formed in a three-dimensional field effect transistor (e.g., a fin-like field effect transistor, or FinFET, a gate-all-around FET, or GAA FET, etc.), a number of methods may be implemented independently or in combination to further process the HKMG structure according to specific design requirements. In one example, the HKMG structure may be cut into two or more portions and subsequently separated by gate isolation structure(s) in a process referred to as cut metal gate (CMG). The gate isolation structures are oriented lengthwise in a direction generally perpendicular to the direction of the HKMG structures.

In some existing technologies, an IC structure includes a memory array and a logic array. To achieved desired functions, gate isolation structures are formed in the memory array and in the logic array to cut gate structures. Those gate isolation structures in the memory array and the logic array may be formed simultaneously and thus have a same composition. However, during operation, the memory cells and the logic cells may need different improved performances. For instance, the logic cells may prefer to have a lower parasitic capacitance to achieve better ring oscillator speed, and the memory cells may prefer to have a better voltage stability and less threshold voltage (Vt) variation. Gate isolation structures with the same composition in the logic array and the memory array are not entirely satisfactory. For example, to reduce parasitic capacitance of the logic array, the gate isolation structures may include a low-k dielectric layer such as an oxide layer. However, oxygen may diffuse into work function layer (e.g., aluminum-containing N-type work function layer) and affect the threshold voltage of the transistor in the memory array. Thus, improvements in methods of processing HKMG structure with parasitic capacitance and less threshold voltage variation are desired.

The present disclosure provides integrated circuit structures and methods for forming gate isolation structures in the integrated circuit structures. In an embodiment, the formation of a gate isolation structure includes forming a trench extending through the HKMG structure and an isolation feature filling the trench. To obtain both low parasitic capacitance in the logic array and low threshold voltage variation in the memory array, the IC structure is fabricated to include hybrid gate isolation structures such that gate isolation structures in the logic array can lead to a reduced parasitic capacitance and gate isolation structures in the memory array can lead to less threshold voltage variations. For example, the gate isolation structures in the memory array may be formed of a nitrogen-containing dielectric material that is free of oxygen or having a low oxygen concentration, and the gate isolation structures in the logic array may include low-k dielectric material. By forming hybrid gate isolation structures, performances of the logic array and memory array can be advantageously improved.

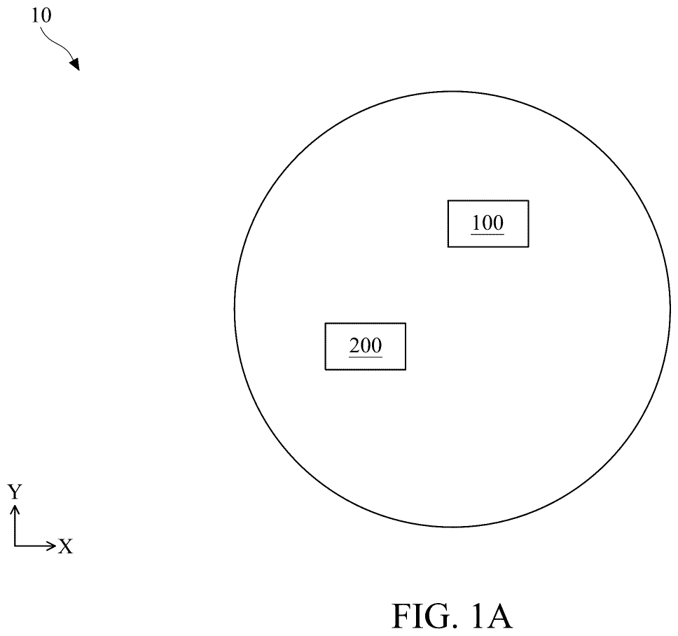

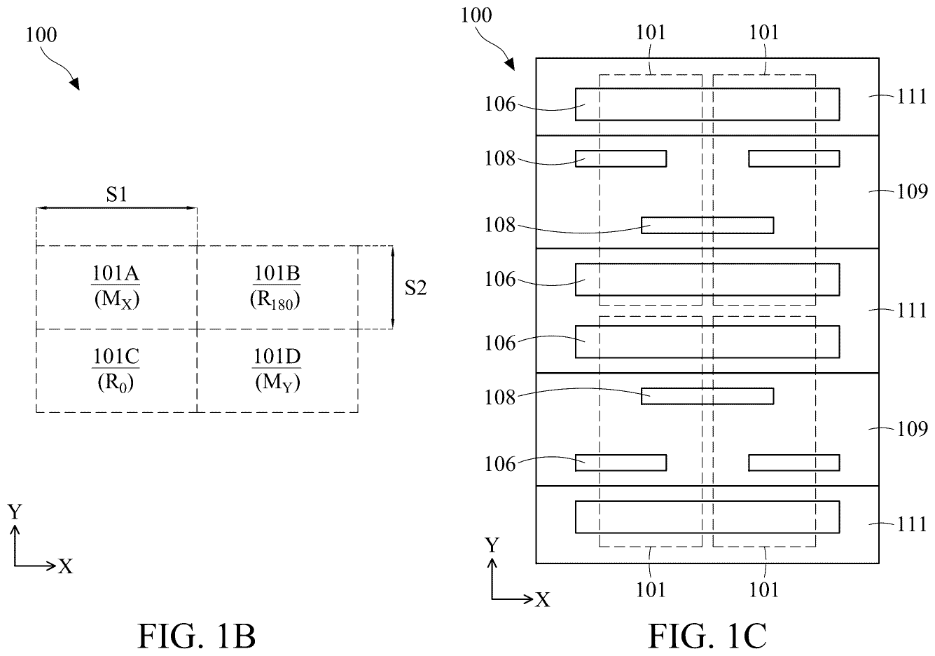

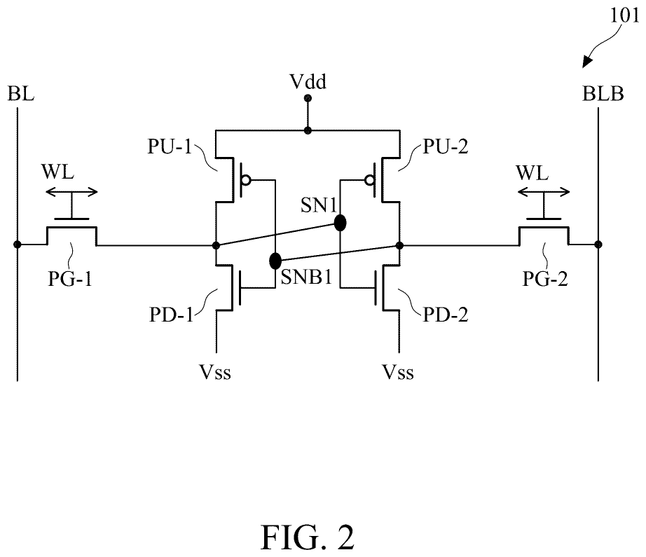

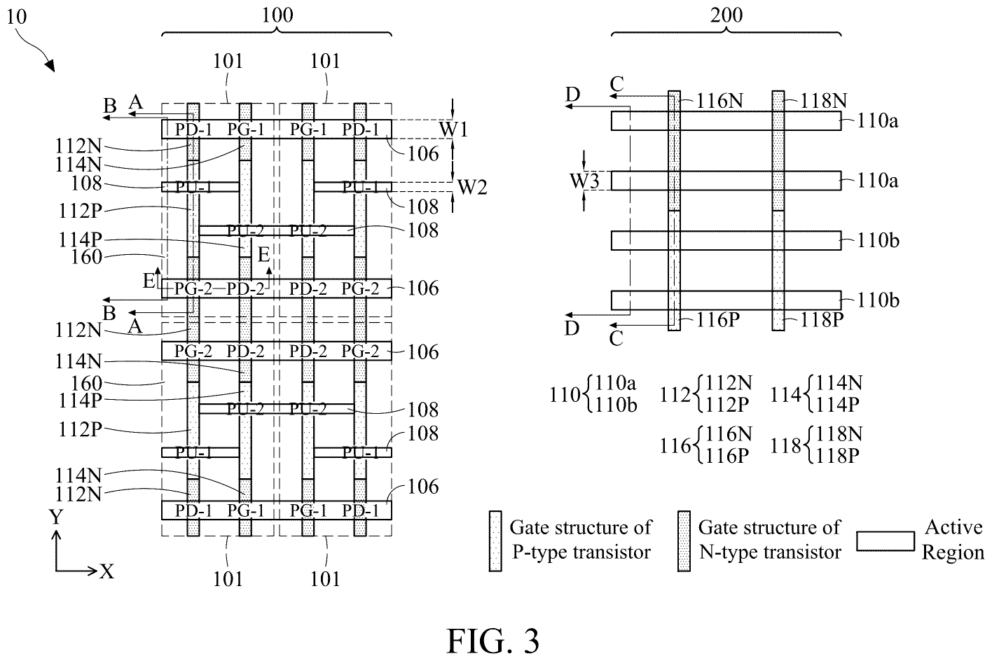

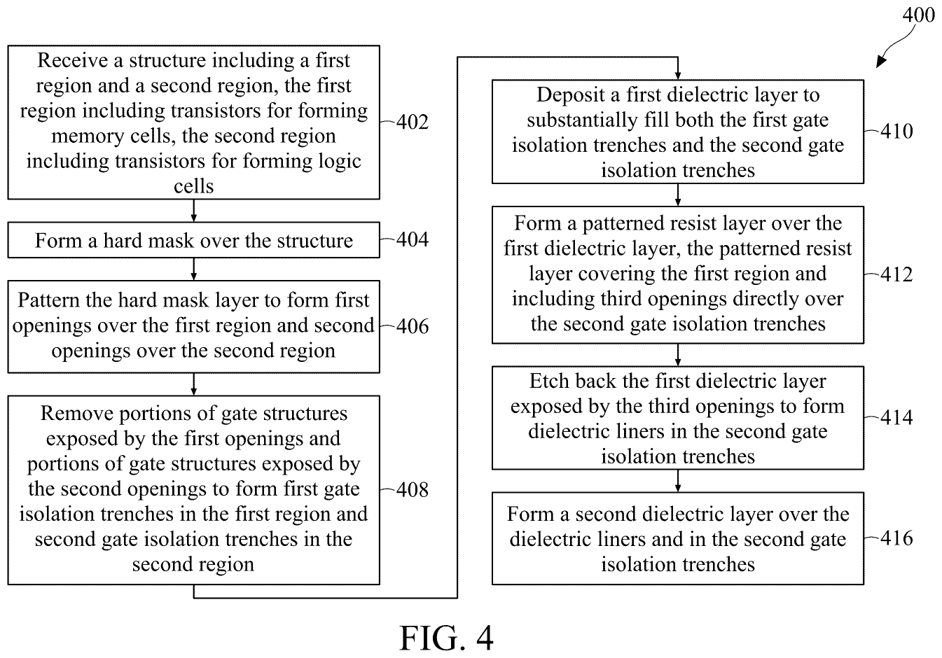

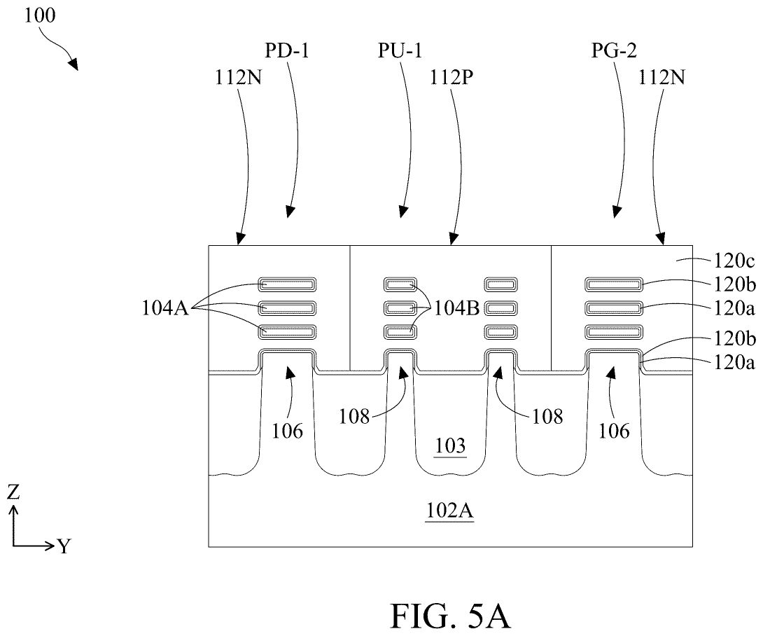

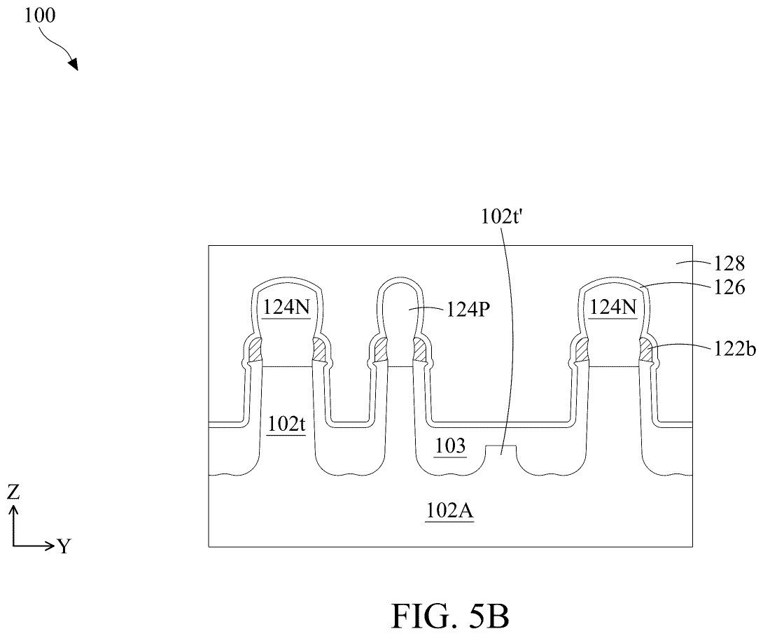

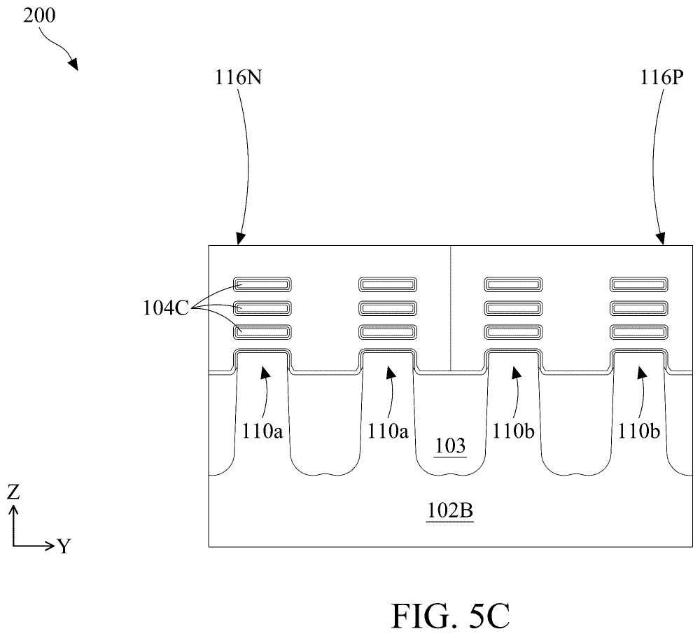

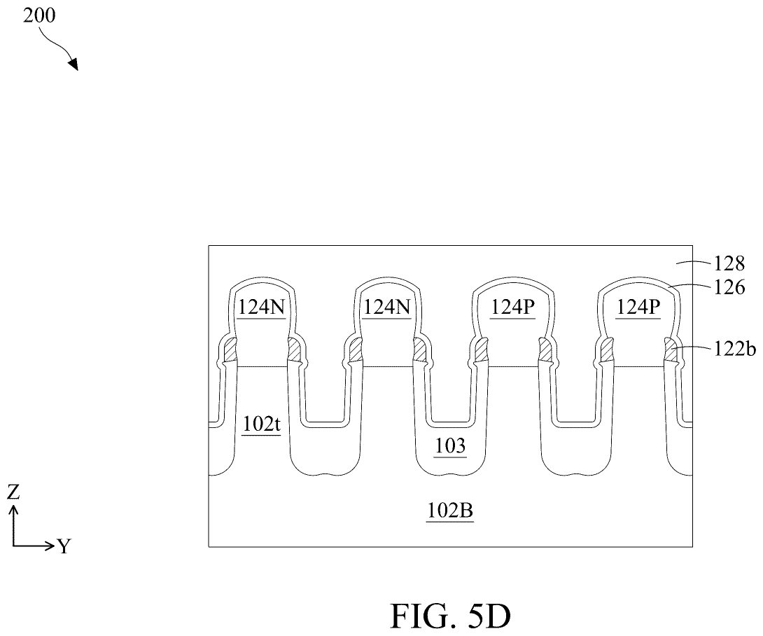

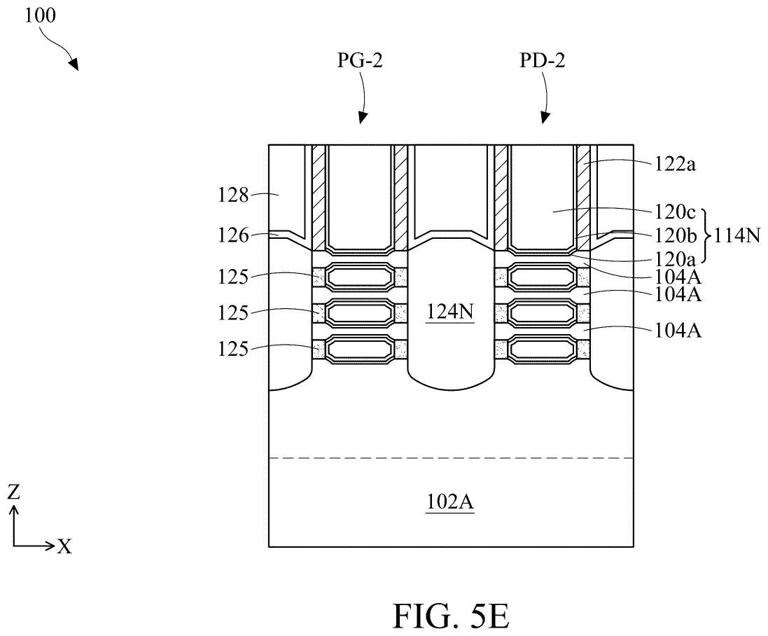

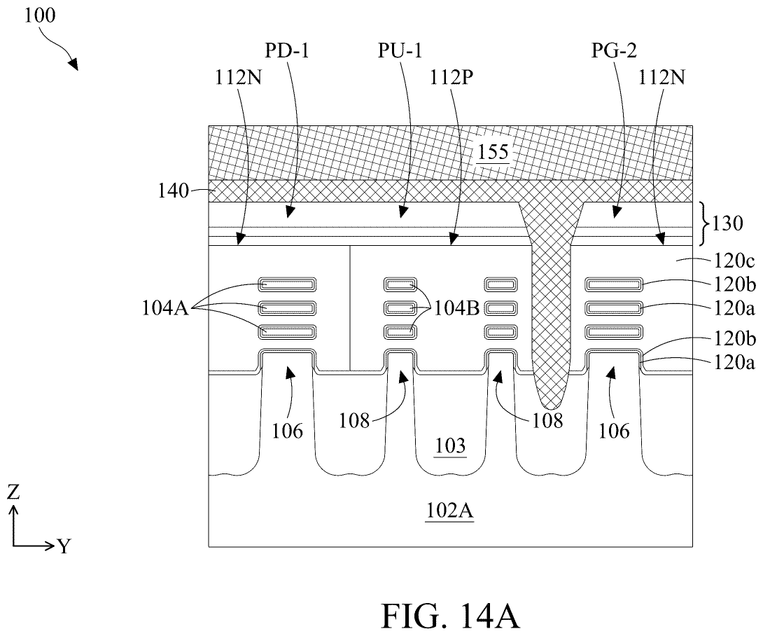

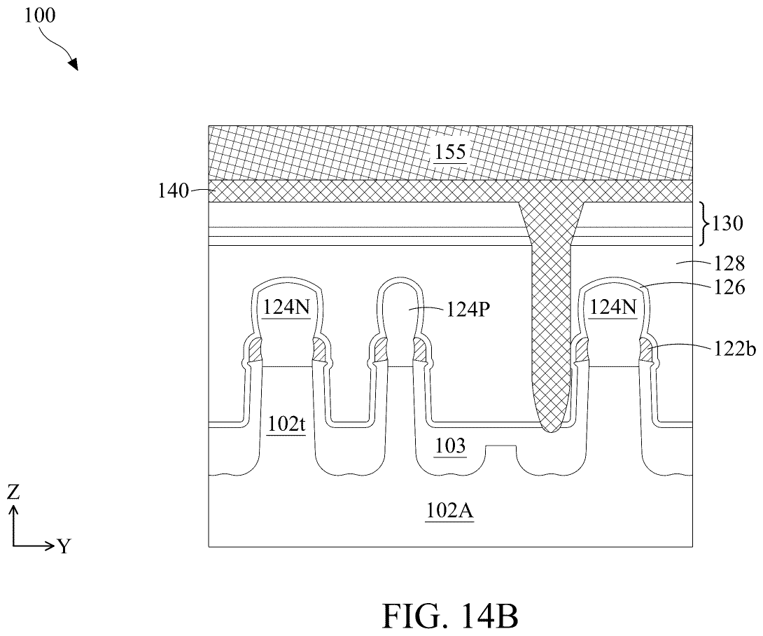

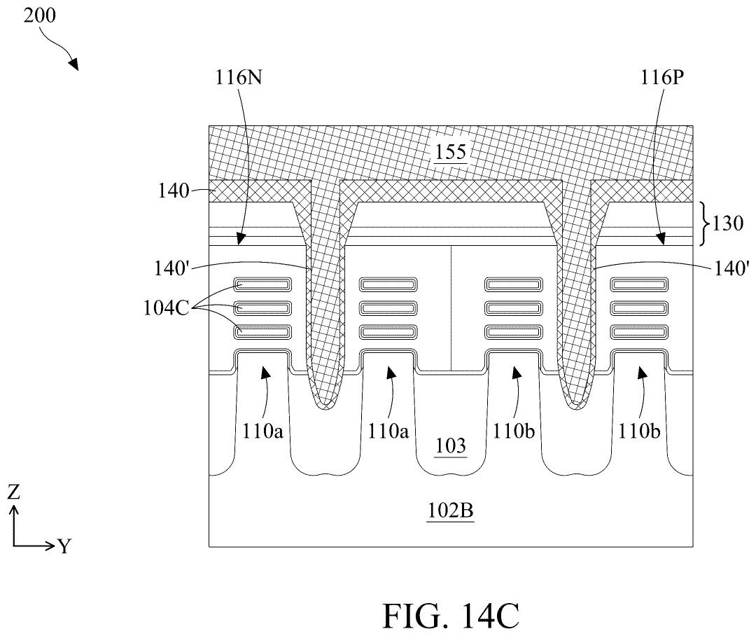

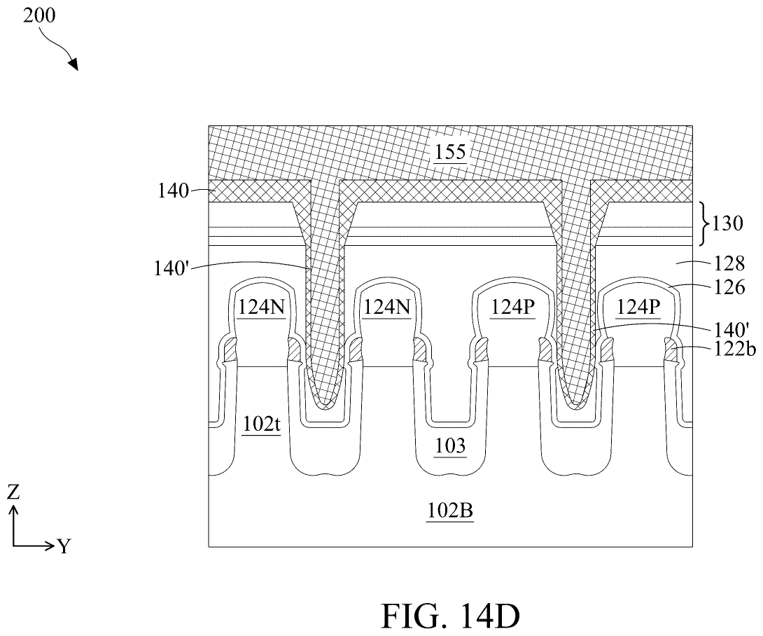

The various aspects of the present disclosure will now be described in more detail with reference to the figures. In that regard, FIG. 1A is a diagrammatic plan view of an exemplary IC structure 10 including a memory array 100 and a logic array 200. FIGS. 1B and 1C are diagrammatic plan views of the memory array 100. FIG. 2 is a circuit diagram of an SRAM cell that can be implemented in the memory array 100. FIG. 3 is a fragmentary top, plan view of the IC structure 10 including the memory array 100 and a logic array 200, according to various aspects of the present disclosure. FIG. 4 is a flow chart illustrating method 400 of forming first gate isolation structures in the memory array 100 and second gate isolation structures in the logic array 200. Method 400 is described below in conjunction with FIGS. 5A-20. Method 400 is merely an example and is not intended to limit the present disclosure to what is explicitly illustrated therein. Additional steps may be provided before, during, and/or after the method 400, and some steps described can be replaced, eliminated, or moved around for additional embodiments of the method. Not all steps are described herein in detail for reasons of simplicity. For avoidance of doubts, the X, Y and Z directions in the figures are perpendicular to one another and are used consistently throughout the present disclosure. Throughout the present disclosure, like reference numerals denote like features unless otherwise excepted.

Referring to FIG. 1A, the present disclosure provides an IC structure 10 formed over a semiconductor substrate 102 and includes at least an array 100 of memory cells. The array 100 may include static random-access memory (SRAM) cells, dynamic random-access memory (DRAM) cells, non-volatile random-access memory (NVRAM) cells, flash memory cells, other suitable memory cells, or combinations thereof. The array 100 may be hereafter referred to as a memory array 100 or a SRAM array 100. The IC structure 10 may further include a number of other components, such as an array 200 of standard logic (STD) cells configured to provide various standard logic devices, such as inverter, AND, NAND, OR, XOR, NOR, other suitable devices, or combinations thereof. As such, the array 200 is hereafter referred to as a logic array 200. Additionally, the IC structure 10 may include various passive and active microelectronic devices, such as resistors, capacitors, inductors, diodes, bipolar transistors, high voltage transistors, high frequency transistors, other suitable devices, or combinations thereof. Additional features can be added to the IC structure 10 and some of the features described below can be replaced, modified, or eliminated in other embodiments of the IC structure 10.

In the present embodiments, referring to FIG. 1B, the memory array 100 includes a number of memory cells 101A, 101B, 101C, and 101D. The memory cells each may be an SRAM cell. For case of description, the memory cells 101A, 101B, 101C, and 101D may be hereinafter referred to as SRAM cells 101A, 101B, 101C, and 101D, respectively. The SRAM cells 101A, 101B, 101C, and 101D generally provide memory or storage capable of retaining data when power is applied. Each of the SRAM cells 101A-101D includes one or more transistors (e.g., FinFETs or GAA transistors) to be described in detail below. The SRAM cells 101A, 101B, 101C, and 101D, together defining a two-by-two grid, exhibit mirror and/or rotational symmetry with respect to each other. For example, using the SRAM cell 101C as a reference (denoted “R₀”), a layout of the SRAM cell 101A (denoted “M_{X}”) is a mirror image of a layout of the SRAM cell 101C with respect to the X direction. Similarly, a layout of the SRAM cell 101B is a mirror image of the layout of the SRAM cell 101A, and a layout of the SRAM cell 101D (denoted “My”) is a mirror image of the layout of the SRAM cell 101C, both with respect to the Y direction. In other words, the layout of the SRAM cell 101B (denoted “R₁₈₀”) is symmetric to the layout of the SRAM 101C by a rotation of 180 degrees about a geometric center of the grid, which is defined as an intersection point of an imaginary line bisecting the rectangular grid along the Y direction and an imaginary line bisecting the rectangular grid along the X direction. Furthermore, in the depicted embodiments, the SRAM cells 101A-101D are substantially the same in size, i.e., having substantially the same horizontal pitch S1 along the X direction and a vertical pitch S2 along the Y direction. Each SRAM cells 101A-101D may hereafter be referred to as the SRAM cell 101 for purposes of simplicity.

Referring to FIG. 1C, each SRAM cell 101 is configured to include active regions 106 disposed over a p-type doped region 111 (hereafter referred to as p well 111) and active regions 108 disposed over an n-type doped region 109 (hereafter referred to as n well 109), which is interposed between two p wells 111. The active regions 106 and the active regions 108 are oriented lengthwise along X direction and spaced from each other along Y direction, which is substantially perpendicular to the X direction. In the present embodiments, channel regions of each of the active regions 106 and active regions 108 may include a number of nanostructures (e.g., nanosheets) and a final structure of the SRAM array 100 includes GAA transistors. In some other embodiments, the active regions 106 and active regions 108 each may include a uniform semiconductor composition along the Z direction, and a final structure of the SRAM array 100 includes FinFETs. The active regions 106 are configured to form n-type transistors, and the active regions 108 are configured to form p-type transistors. Various SRAM cells 101 may be configured for similar applications, such as a high-speed application, a low-power application, other suitable applications, or combinations thereof. Alternatively, different SRAM cells 101 may be configured for different applications and designed with different specifications (e.g., dimensions, layout designs, etc.) accordingly. Various aspects and embodiments of the SRAM cell 101 and the SRAM array 100 are described in detail below.

FIG. 2 illustrates an exemplary circuit schematic for a single-port SRAM cell (e.g., 1-bit SRAM cell) 101. The single-port SRAM cell 101 includes pull-up transistors PU-1, PU-2; pull-down transistors PD-1, PD-2; and pass-gate transistors PG-1, PG-2. As show in the circuit diagram, transistors PU-1 and PU-2 are p-type transistors, and transistors PG-1, PG-2, PD-1, and PD-2 are n-type transistors. Since the SRAM cell 101 includes six transistors in the illustrated embodiment, it may also be referred to as a 6T SRAM cell.

The drains of pull-up transistor PU-1 and pull-down transistor PD-1 are coupled together, and the drains of pull-up transistor PU-2 and pull-down transistor PD-2 are coupled together. Transistors PU-1 and PD-1 are cross-coupled with transistors PU-2 and PD-2 to form a first data latch. The gates of transistors PU-2 and PD-2 are coupled together and to the drains of transistors PU-1 and PD-1 to form a first storage node SN1, and the gates of transistors PU-1 and PD-1 are coupled together and to the drains of transistors PU-2 and PD-2 to form a complementary first storage node SNB1. Sources of the pull-up transistors PU-1 and PU-2 are coupled to a power voltage Vdd, and the sources of the pull-down transistors PD-1 and PD-2 are coupled to a voltage Vss, which may be an electrical ground in some embodiments. The first storage node SN1 of the first data latch is coupled to bit line BL through pass-gate transistor PG-1, and the complementary first storage node SNB1 is coupled to complementary bit line BLB through pass-gate transistor PG-2. The first storage node SN1 and the complementary first storage node SNB1 are complementary nodes that are often at opposite logic levels (logic high or logic low). Gates of pass-gate transistors PG-1 and PG-2 are coupled to a word line WL. Although a single-port 6T SRAM cell is illustrated, the present disclosure is also applicable to other memory cells, such as dual-port SRAM cells.

FIG. 3 is a fragmentary top, plan view of an intermediate structure of the IC structure 10 including the memory array 100 the logic array 200 before forming gate isolation structures, according to various aspects of the present disclosure. Additional features can be added to the fragmentary top, plan view of the IC structure 10 and some of the features described below can be replaced, modified, or eliminated in other embodiments. FIG. 5A illustrates a fragmentary cross-sectional view of the IC structure 10 taken along line A-A as shown in FIG. 3, FIG. 5B illustrates a fragmentary cross-sectional view of the IC structure 10 taken along line B-B as shown in FIG. 3, FIG. 5C illustrates a fragmentary cross-sectional view of the IC structure 10 taken along line C-C as shown in FIG. 3, FIG. 5D illustrates a fragmentary cross-sectional view of the IC structure 10 taken along line D-D as shown in FIG. 3, and FIG. 5E illustrates a fragmentary cross-sectional view of the IC structure 10 taken along line E-E as shown in FIG. 3.

Reference is first made to portion of the SRAM array 100 shown in FIG. 3. In the present embodiments, referring to FIGS. 3 and FIGS. 5A-5E, the SRAM array 100 (as a portion of the IC structure 10) is formed over a first region 102A of a substrate (or a wafer) 102. The substrate 102 may be a bulk silicon substrate (i.e., including bulk single-crystalline silicon). The substrate 102 may include other semiconductor materials in various embodiments, such as germanium, silicon carbide, gallium arsenide, gallium phosphide, indium phosphide, indium arsenide, indium antimonide, SiGe, GaAsP, AlInAs, AlGaAs, GalnAs, GalnP, GalnAsP, or combinations thereof, or other suitable materials. In some alternative embodiments, the substrate 102 may be a semiconductor-on-insulator substrate, such as a silicon-on-insulator (SOI) substrate, a silicon germanium-on-insulator (SGOI) substrate, or a germanium-on-insulator (GOI) substrate.

The first region 102A of the substrate 102 includes a number of p wells (p-type doped regions) 111 (shown in FIG. 1C) and n wells (n-type doped regions) 109 (shown in FIG. 1C) formed therein (and/or thereover) according to various design requirements of the SRAM array 100. The n well 109 is configured to provide at least one p-type field-effect transistor (PFET), such as a pull-up transistor, and each p well 111 is configured to provide at least one n-type field-effect transistor (NFET), such as a pull-down transistor or a pass-gate transistor. In some embodiments, the substrate 102 may include additional doped regions configured to provide one or more transistors according to design requirements of the SRAM array 100 and the logic array 200.

In the present embodiments represented by FIG. 3, FIGS. 5A-5B and 5E, for the SRAM array 100, each SRAM cell 101 includes two active regions 106 each disposed in a p well 111 and two active regions 108 disposed in an n well 109 interposing between the two p wells 111. The active regions 106 and active regions 108 extend lengthwise along the X direction. Each of the active regions 106 and 108 includes channel regions and source/drain regions. Each channel region of the active regions may be disposed laterally adjacent to source/drain regions. In this illustrated embodiment, each channel region includes a number of nanostructures (104A, 104B shown in FIG. 5A). The active regions 106 and active regions 108 may be formed from a top portion of the substrate 102 and a vertical stack of alternating semiconductor layers using a combination of lithography and etch steps. The top portion of the substrate 102 that is patterned during the formation of the active regions may be referred to as a protrusion 102t, a base portion 102t, a base fin 102t, or a mesa structure 102t. In the cross-sectional view represented by FIG. 5B, to form SRAM cells with desired functions, a part 102t′ of the base fin 102t of the active region 108 is recessed. That is, the recessed part 102t′ of the base fin 102t has a height less than a height of a remaining part of the base fin 102t. In the depicted embodiment, the vertical stack of alternating semiconductor layers includes a number of channel layers interleaved by a number of sacrificial layers. Each channel layer may include a semiconductor material such as, silicon, germanium, silicon carbide, silicon germanium, GeSn, SiGeSn, SiGeCSn, other suitable semiconductor materials, or combinations thereof, while each sacrificial layer has a composition different from that of the channel layer. In an embodiment, the channel layer includes silicon (Si), the sacrificial layer includes silicon germanium (SiGe). The channel layers and the sacrificial layers may be epitaxially deposited on the substrate 102 using molecular beam epitaxy (MBE), vapor-phase epitaxy (VPE), ultra-high vacuum CVD (UHV-CVD), and/or other suitable epitaxial growth processes. In some examples, each of the active regions 106 and active regions 108 may include a total of three to ten pairs of alternating sacrificial layers and channel layers; of course, other configurations may also be applicable depending upon specific design requirements. The sacrificial layers are then removed during subsequent fabrication process to release the channel layers as nanostructures. For embodiments in which the transistors in the SRAM cells 101 include FinFETs, each channel region may include a fin protruding from the substrate 102. In this illustrated embodiment, the channel region of the active region 106 includes nanostructures 104A, and the channel region of the active region 106 includes nanostructures 104B, and a width W1 (shown in FIG. 3) of the nanostructures 104A is greater than a width W2 (shown in FIG. 3) of the nanostructures 104B.

The SRAM array 100 also includes isolation features (such as isolation features 103 shown in FIG. 5A) disposed over the substrate 102 to electrically separate two adjacent active regions. In some embodiments, the isolation features 103 are deposited in trenches that define the active regions 106 and/or the active regions 108. In an exemplary process, a dielectric material for forming the isolation features is deposited over the substrate 102 using chemical vapor deposition (CVD), sub-atmospheric CVD (SACVD), flowable CVD (FCVD), physical vapor deposition (PVD), spin-on coating, and/or other suitable process. Then the deposited dielectric material is planarized and recessed until the active regions 106 and 108 rise above the isolation features 103. In this illustrated embodiment, the isolation feature 103 extends over the recessed part 102t′ of the base fin 102t. The dielectric material for the isolation features 103 may include silicon oxide, silicon oxynitride, fluorine-doped silicate glass (FSG), a low-k dielectric, combinations thereof, and/or other suitable materials. The isolation features 103 may be shallow trench isolation (STI) features. In an embodiment, the isolation feature includes a dielectric fill layer, a first dielectric liner extending along sidewalls and bottom surface of the dielectric fill layer, and a second dielectric liner extending along sidewalls and bottom surface of the first dielectric liner, the first dielectric liner and the second dielectric liner have different compositions.

Still referring to FIG. 3, FIGS. 5A-5B and 5E, the SRAM array 100 also includes a number of gate structures (e.g., gate structures 112, 114) oriented lengthwise along the Y direction and engaging the active regions 106 and the active regions 108 to form various transistors. Each gate structure traverses channel regions of active regions 106 and 108. In the depicted embodiments, referring to FIG. 3 as an example, portions of the gate structure 114 engages a first one of the active regions 106 to form a pass-gate transistor PG-1 and a second one of the active regions 106 to form a pull-down transistor PD-2 in the upper left SRAM cell 101, and further engages a third one of the active regions 106 to form a pull-down transistor PD-2 and a fourth one of the active regions 106 to form a pass-gate transistor PG-1 in the lower left SRAM cell 101. Portions of the gate structure 114 also engages a first one of the active regions 108 to form a pull-up transistor PU-2 in the upper left SRAM cell 101 and a second one of the active regions 108 to form a pull-up transistor PU-2 in the lower left SRAM cell 101. Similarly, portions of the gate structures 112 also engage the active regions 106 and active regions 108 to form various transistors PD-1, PU-1, PG-2 in the SRAM array 100. In some embodiments, the pull-up transistor PU-1 and the PU-2 are configured as p-type transistors, while the pull-down transistor PD-1, PD-2, and the pass-gate transistors PG-1, PG-2 are configured as n-type transistors. N-type transistors include gate structures containing n-type work function layers, and thus portions of the gate structures 112 and 114 that are configured to form n-type transistors are hereinafter referred to as gate structures 112N and 114N, respectively. P-type transistors include gate structures containing p-type work function layers, and thus portions of the gate structures 112 and 114 that are configured to form p-type transistors are hereinafter referred to as gate structures 112P and 114P, respectively. The gate structure 112 incudes multiple gate structures 112N and gate structures 112P, and the gate structure 114 incudes multiple gate structures 114N and gate structures 114P.

Reference is then made to portion of the logic array 200 shown in FIG. 3. In the present embodiments represented by FIG. 3 and FIGS. 5C-5D, the logic array 200 includes two active regions 110a and two active regions 110b over a second region 102B of the substrate 102. The second region 102B of the substrate 102 includes a number of p wells (not shown) and n wells (not shown) formed therein (and/or thereover) according to various design requirements of the logic array 200. For example, the two active regions 110a are disposed over a p well, and two active regions 110b are disposed over an n well (not shown). The active regions 110a and 110b extend lengthwise along the X direction. Each of the active regions 110a and 110b includes channel regions and source/drain regions. Each channel region of the active regions may be disposed laterally adjacent to source/drain regions. In this illustrated embodiment, each channel region includes a number of nanostructures (104C shown in FIG. 5C) over the protrusion 102t. The active regions 110a-110b are substantially the same as the active regions 106-108 in terms of fabrication process and composition. One of the differences between the active region 110a-110b and the active region 106-108 includes that, the active regions 110a-110b have a same width, and a width W3 (shown in FIG. 3) of nanostructures 104C of the active region 110a-110b may be different than (e.g., greater than, or less than) the width W1 of the nanostructures 104A. In an embodiment, the width W3 is greater than the width W2 and less than the width W1. The active region 110a and the active region 110b may be individually or collectively referred to as the active region 110.

The logic array 200 also includes the isolation features 103 (shown in FIG. 5C) disposed over the substrate 102 to electrically separate two adjacent active regions. The logic array 200 also includes a number of gate structures (e.g., gate structures 116, 118) oriented lengthwise along the Y direction and engaging the active regions 110 to form various transistors. Each gate structure traverses a channel region of at least one active region 110. In the depicted embodiments, referring to FIG. 3 as an example, portions of the gate structure 116 engages two active regions 110a to form n-type transistors and engages another two active regions 110b to form p-type transistors. N-type transistors include gate structures containing n-type work function layers, and thus portions of the gate structures 116 and 118 that are configured to form n-type transistors are hereinafter referred to as gate structures 116N and 118N, respectively. P-type transistors include gate structures containing p-type work function layers, and thus portions of the gate structures 116 and 118 that are configured to form p-type transistors are hereinafter referred to as gate structures 116P and 118P, respectively.

To obtain SRAM arrays and logic arrays that are capable of performing desired functions, gate structures of some transistors may be electrically isolated. For example, in the upper left SRAM cell 101, gate structure 112P of pull-up transistor PU-1 will be coupled to the complementary first storage node SNB1, and gate structure 112N of pass-gate transistors PG-2 will be coupled to the word line WL. Thus, a gate isolation structure will be formed to provide isolation between the gate structure 112P of pull-up transistor PU-1 and the gate structure 112N of pass-gate transistors PG-2. Similarly, the logic array 200 also needs gate isolation structures to provide isolation between different portions of the gate structure 116/118 to achieve desired logic functions. As described above, to provide improved performance for both the memory array 100 and the logic array 200, hybrid gate isolation structures in the IC structure 20 are provided.

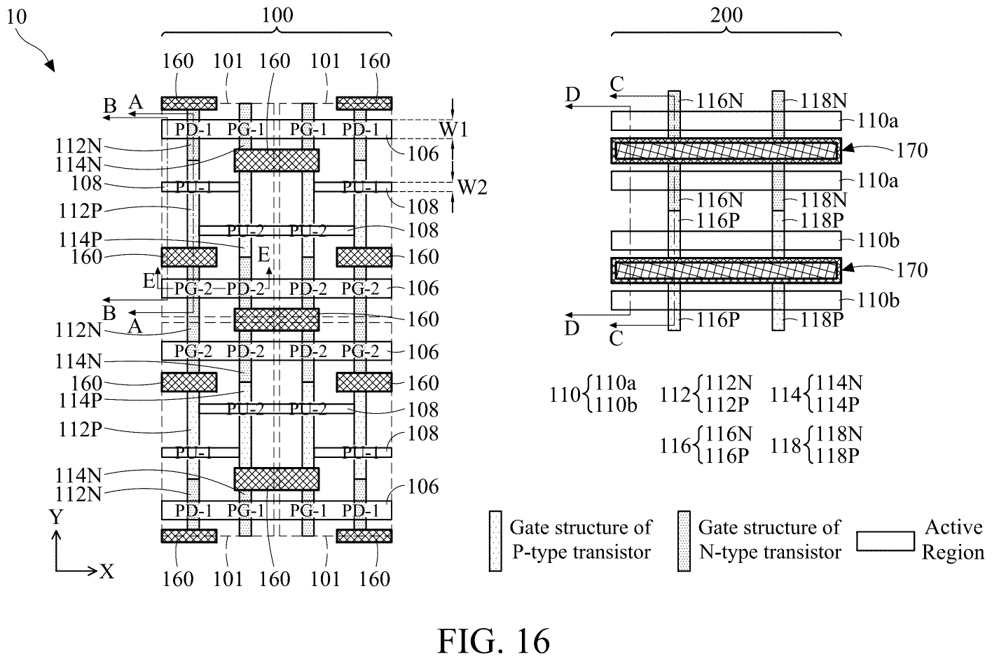

Method for forming the hybrid gate isolation structures is described with reference to FIGS. 4-16. FIG. 4 illustrates a flowchart of an exemplary method 400 for fabricating the hybrid gate isolation structures in the IC structure 10, according to various embodiments of the present disclosure. Method 400 is described below in conjunction with FIGS. 5A-15D, which are fragmentary cross-sectional views and top views of the IC structure 10 during various fabrication stages in the method 400 of FIG. 4. FIG. 16 is a fragmentary top, plan view of an intermediate structure of the IC structure 10 including first gate isolation structures 160 in the memory array 100 and second gate isolation structures 170 in the logic array, according to various aspects of the present disclosure.

Referring now to FIGS. 4 and 5A-5E, method 400 includes a block 402 where the IC structure 10 represented by FIG. 3 is received. FIGS. 5A, 5B, 5C, 5D, 5E illustrates fragmentary cross-sectional views of the IC structure 10 taken along line A-A, B-B, C-C, D-D, E-E, as shown in FIG. 3, respectively. As described above, the IC structure 10 includes the substrate 102. The substrate 102 has the first region 102A for forming transistors (e.g., PU-1, PU-2, PD-1, PD-2, PG-1, PG-2) of the SRAM array 100 thereon and the second region 102B for forming transistors of the logic array 200 thereon.

As described above, each of the transistors of the IC structure 10 includes a gate structure (e.g., gate structure 112, 114, 116, 118) wrapping around and over respective nanostructures (e.g., 104A, 104B, 104C) of corresponding active regions (e.g., 106, 108, 110a, 110b). Each of the gate structures 112, 114, 116 and 118 includes a gate dielectric layer and a gate electrode 120c over the gate dielectric layer. The gate dielectric layer includes an interfacial layer 120a and a high-k dielectric layer 120b. In some instances, the interfacial layer 120a may be formed by thermal oxidation and may include silicon oxide. The high-k dielectric layer 120b is formed of dielectric materials having a high dielectric constant, for example, greater than a dielectric constant of silicon oxide (k≈3.9). Exemplary dielectric materials for the high-k dielectric layer include hafnium oxide, titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr) TiO₃ (BST), silicon nitride (SIN), silicon oxynitride (SiON), combinations thereof, or other suitable materials. In one embodiment, the high-k dielectric layer 120b is formed of hafnium oxide. The gate electrode 120c may include multiple layers, such as work function layers, glue/barrier layers, and/or metal fill (or bulk) layers. A work function layer includes a conductive material tuned to have a desired work function (such as an n-type work function or a p-type work function), such as n-type work function materials and/or p-type work function materials. The gate electrode 120c of each of the gate structures 112P, 114P, 116P and 118P includes a p-type work function layer. Exemplary p-type work function materials include TiN, TaN, Ru, Mo, Al, WN, ZrSi₂, MoSi₂, TaSi₂, NiSi₂, WN, other p-type work function material, or combinations thereof. The gate electrode 120c of each of the gate structures 112N, 114N, 116N and 118N includes an n-type work function layer. Exemplary n-type work function materials include Ti, Al, Ag, Mn, Zr, TiAl, TiAIC, TaC, TaCN, TaSIN, TaAl, TaAIC, TiAIN, other n-type work function material, or combinations thereof. A glue/barrier layer can include a material that promotes adhesion between adjacent layers, such as the work function layer and the metal fill layer, and/or a material that blocks and/or reduces diffusion between gate layers, such as such as the work function layer and the metal fill layer. For example, the glue/barrier layer includes metal (for example, W, Al, Ta, Ti, Ni, Cu, Co, other suitable metal, or combinations thereof), metal oxides, metal nitrides (for example, TiN), or combinations thereof. A metal fill layer can include a suitable conductive material, such as aluminum (Al), copper (Cu), tungsten (W), ruthenium (Ru), titanium (Ti), a suitable metal, or a combination thereof. Sidewalls of the gate structures 112, 114, 116 and 118 are lined with gate spacers 122a (shown in FIG. 5E). In some embodiments, the gate spacers 122a may include silicon carbonitride, silicon oxycarbide, silicon oxycarbonitride, or silicon nitride and may be a multi-layer structure.

Each of the transistors of the IC structure 10 also includes source/drain features. N-type transistors include n-type source/drain features 124N coupled to the channel regions of the active regions 106 and 110a and p-type transistors include p-type source/drain features 124P coupled to the channel regions of the active regions 108 and 110b. Source/drain feature(s) may refer to a source or a drain, individually or collectively dependent upon the context. Exemplary n-type source/drain features 124N may include silicon, phosphorus-doped silicon, arsenic-doped silicon, antimony-doped silicon, or other suitable material and may be in-situ doped during the epitaxial process by introducing an n-type dopant, such as phosphorus, arsenic, or antimony, or ex-situ doped using a junction implant process. Exemplary p-type source/drain features 124P may include germanium, gallium-doped silicon germanium, boron-doped silicon germanium, or other suitable material and may be in-situ doped during the epitaxial process by introducing a p-type dopant, such as boron or gallium, or ex-situ doped using a junction implant process. In some embodiments, the n-type source/drain features 124N and/or the p-type source/drain features 124P each may be a multi-layer structure that includes an undoped semiconductor layer, a lightly doped semiconductor layer, and a heavily doped semiconductor layer. In this embodiment, the IC structure 10 also includes fin sidewall spacers 122b (shown in FIGS. 5B and 5D) disposed adjacent to the source/drain features 124N and 124P and on the isolation features 103. The fin sidewall spacers 122b may be formed along with the formation of the gate spacers 122a and thus have same composition as that of the gate spacers 122a.

The IC structure 10 also includes inner spacer features 125 (shown in FIG. 5E) disposed between two vertically adjacent nanostructures (e.g., 104A, 104B, or 104C) and in direct contact with the corresponding source/drain features 124N or 124P. The inner spacer features 125 are disposed laterally between the corresponding source/drain features 124N or 124P and corresponding gate structures 112/114/116/118. The inner spacer features 125 may include silicon nitride, silicon oxycarbonitride, silicon carbonitride, silicon oxide, silicon oxycarbide, silicon carbide, silico oxynitride, other suitable materials, or combinations thereof.

Still referring to FIGS. 5A-5E, the IC structure 10 also includes a contact etch stop layer (CESL) 126 and an interlayer dielectric (ILD) layer 128 deposited over the source/drain features 124N and 124P. The CESL 126 may include silicon nitride, silicon oxynitride, and/or other materials known in the art and may be formed by atomic layer deposition (ALD), plasma-enhanced chemical vapor deposition (PECVD) process and/or other suitable deposition or oxidation processes. The CESL 126 may be deposited on top surfaces of the source/drain features 124N-124P and sidewalls of the gate spacers 122a and fin sidewall spacers 122b. In an embodiment, the CESL 126 is a dual-layer structure that includes a first conformal etch stop layer and a second conformal etch stop layer on the first conformal etch stop layer. The first and second conformal etch stop layers have different compositions. The ILD layer 128 may be deposited by a PECVD process or other suitable deposition technique after the deposition of the CESL 126. The ILD layer 128 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials.

In some embodiments, a gate replacement process (or gate-last process) may be adopted where some dummy gate stacks (not shown) serve as placeholders for those functional gate structures 112, 114, 116 and 118. In an example gate last process, dummy gate stacks (not shown) are formed over channel regions of the active regions 106, 108, 110a, 110b. Each dummy gate stacks may include a gate dielectric layer (e.g., SiO₂) and a dummy gate electrode layer (e.g., polysilicon) formed thereon. The gate spacers 122a are then deposited over the IC structure 10, including over sidewalls of the dummy gate stacks. Source/drain features 124N and 124P may be formed after the forming of the dummy gate stacks. After forming the CESL 126 and the ILD layer 128, a planarization process, such as a CMP (chemical mechanical polishing) process, may be performed to remove excess materials to expose the dummy gate stacks. The dummy gate stacks and sacrificial layers of the active regions are then removed and replaced with the gate structures 112, 114, 116 and 118, the composition of which has been described above.

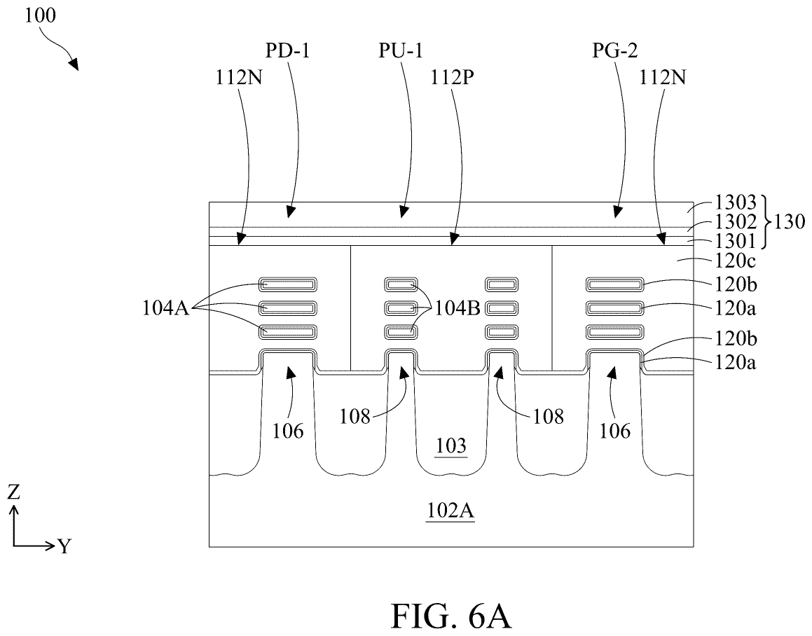

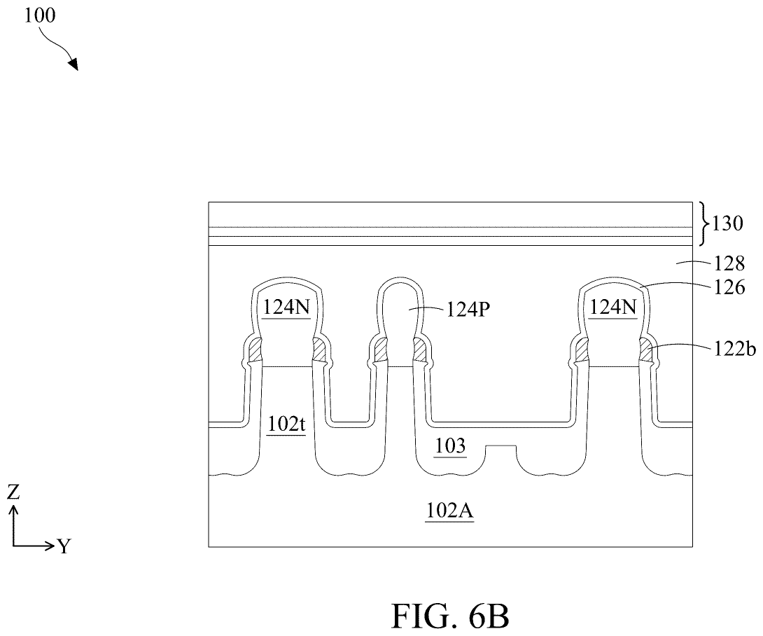

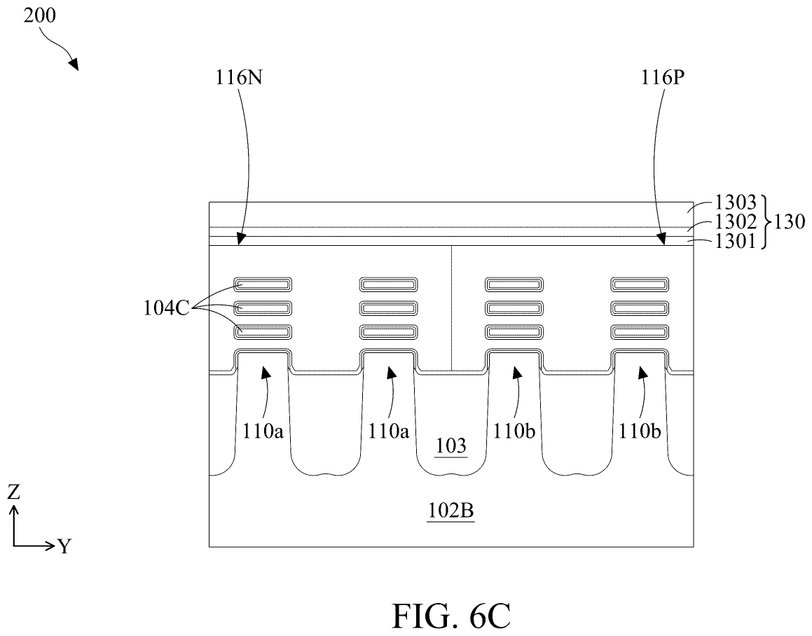

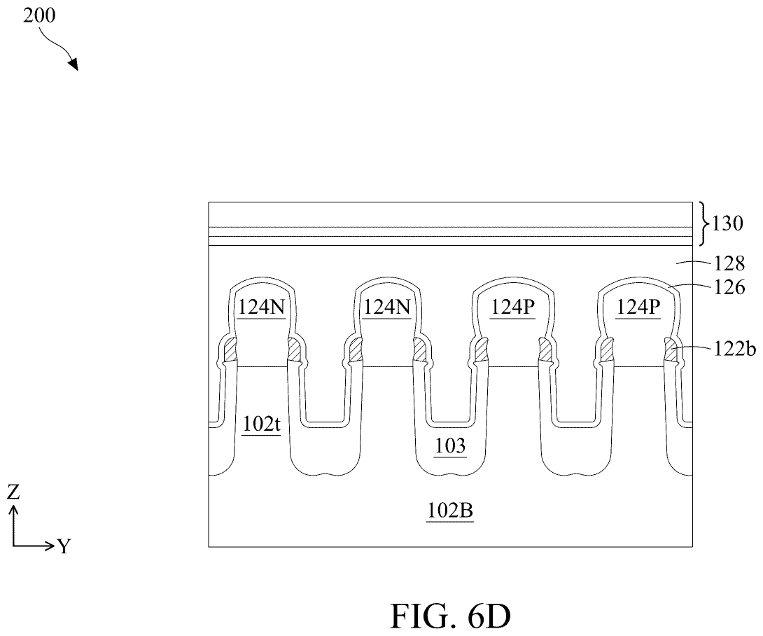

Referring now to FIGS. 4 and 6A-6D, method 400 includes a block 404 where a hard mask 130 is formed over the IC structure 10. In this illustrated embodiment, the hard mask 130 includes a first layer 1301, a second layer 1302 over the first layer 1301, and a third layer 1303 over the second layer 1302. Each of the first layer 1301, second layer 1302, and third layer 1303 may include aluminum oxide, silicon, silicon oxide, silicon nitride, silicon carbonitride, silicon oxycarbide, silicon oxynitride, silicon oxycarbonitride, or other suitable materials and may be formed by CVD, ALD, PVD, other suitable methods, or combinations thereof. In an embodiment, the first layer 1301 includes silicon nitride, the second layer 1302 includes silicon, and the third layer 1303 includes silicon nitride. In an embodiment, a thickness of the third layer 1303 is greater than a thickness of the second layer 1302 and a thickness of the first layer 1301.

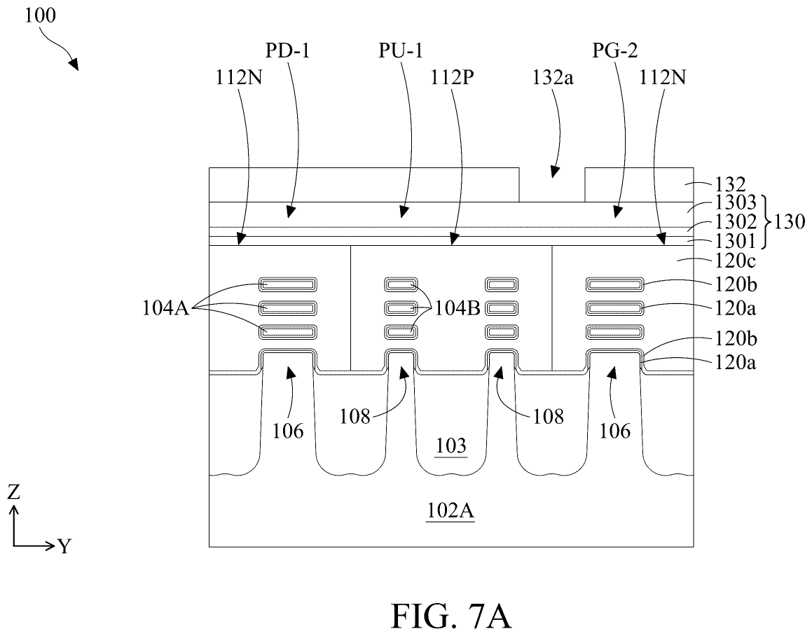

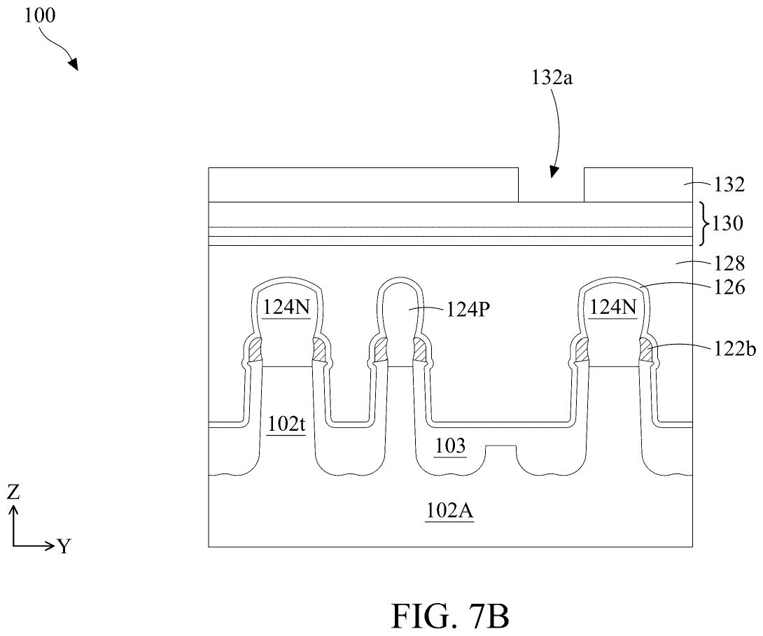

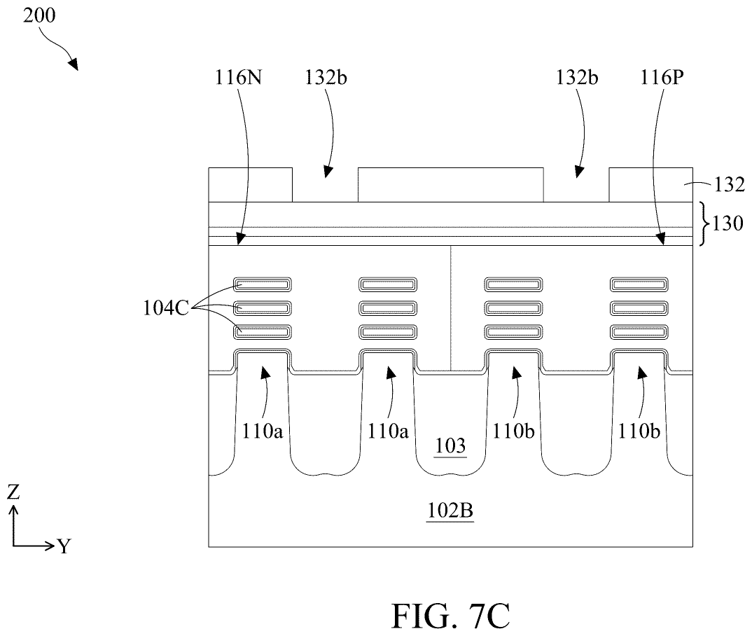

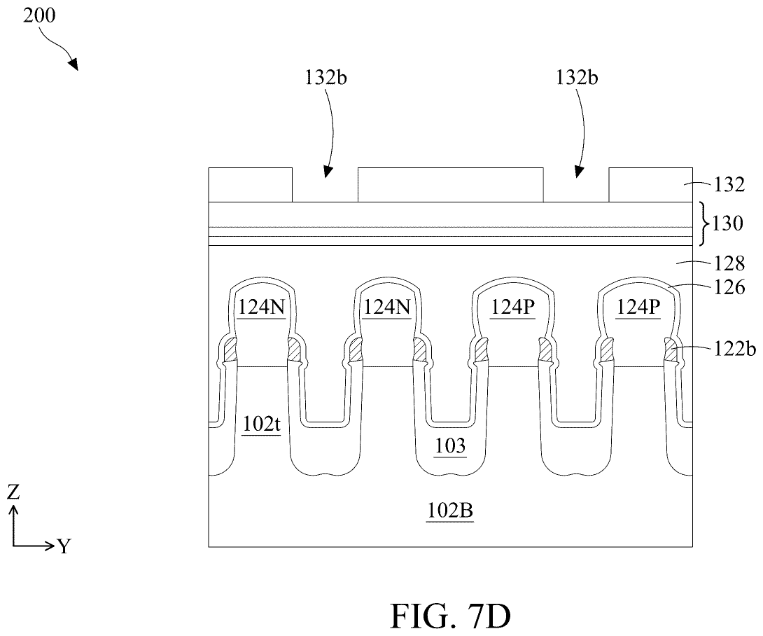

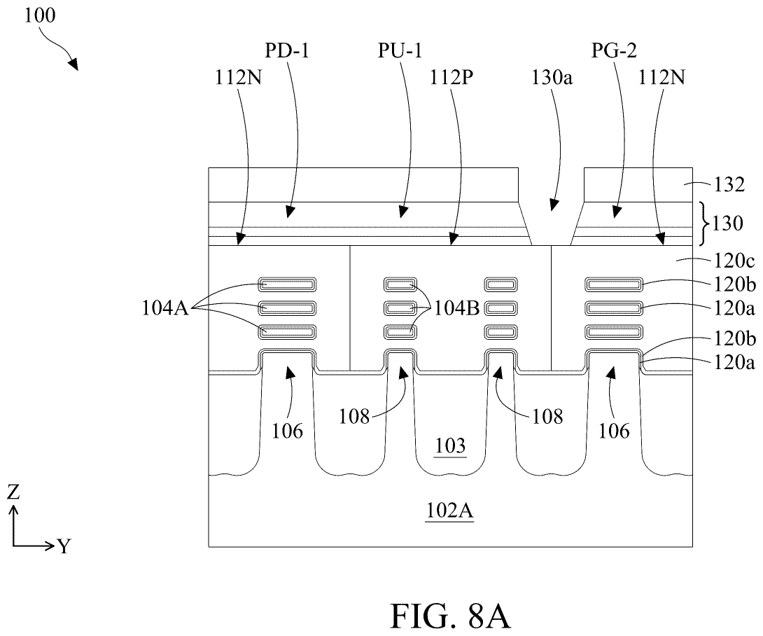

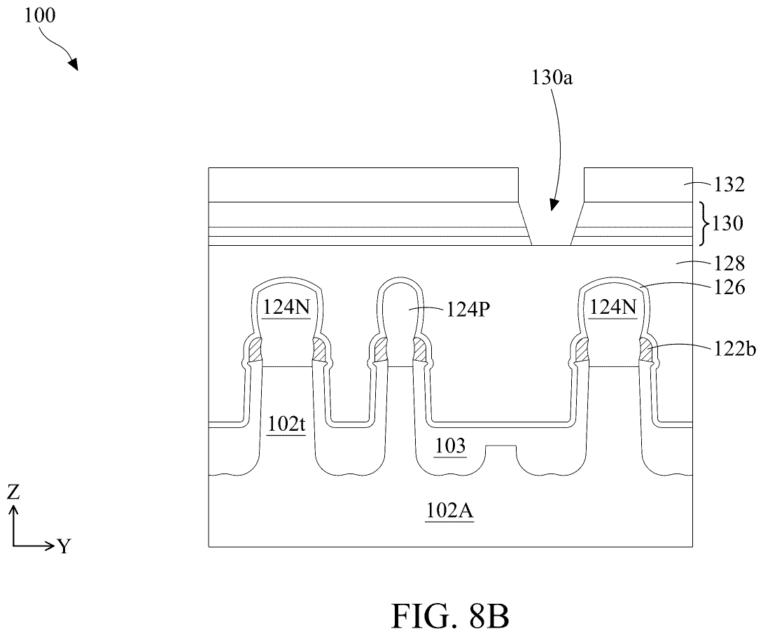

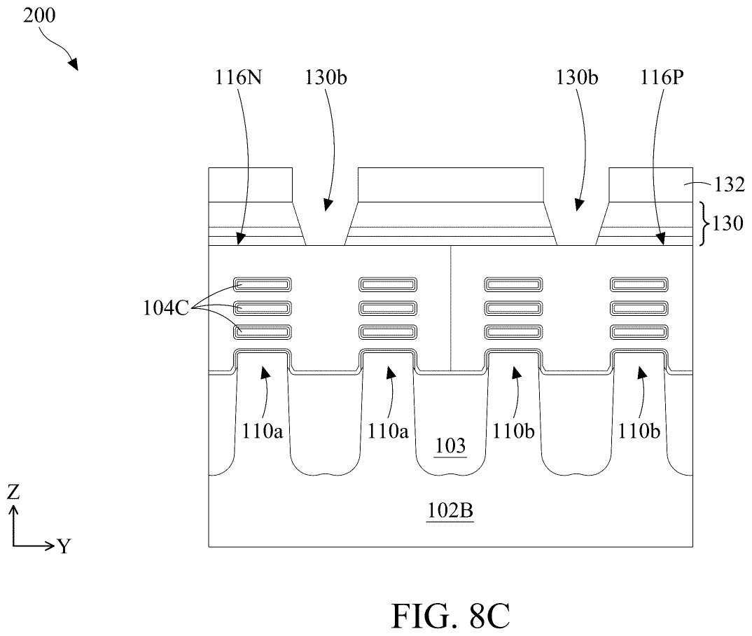

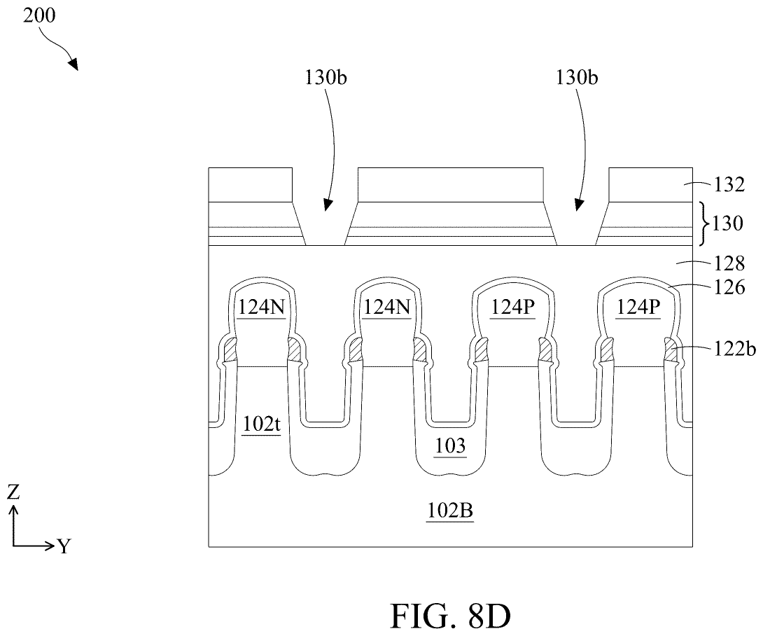

Referring now to FIGS. 4 and 7A-7D and 8A-8D, method 400 includes a block 406 where the hard mask 130 is patterned to form first openings 130a (shown in FIGS. 8A-8B) over the first region 102A and second openings 130b (shown in FIGS. 8C-8D) over the second region 102B. With reference to FIGS. 7A-7D, a masking element including a photoresist layer is formed over the hard mask 130, exposed to a radiation source through a patterned mask, and subsequently developed to form a patterned masking element 132 having openings 132a over the first region 102A and openings 132b over the second region 102B. With reference to FIGS. 8A-8D, the hard mask 130 is then patterned using the patterned masking element 132 as an etch mask to form the first openings 130a over the first region 102A and second openings 130b over the second region 102B. Although not shown, when viewed from top, the gate structures 112, 114, 116, 118 may extend lengthwise along the Y direction, and the first openings 130a and second openings 130b may extend lengthwise along the X direction. The first openings 130a expose portions of some of the gate structures (e.g., gate structures 112 and 114) of transistors in the SRAM array 100, and the second openings 130b expose portions of some of the gate structures (e.g., gate structures 116 and 118) of transistors in the logic array 200. In the illustrated cross-sectional views represented by FIGS. 8A-8B, one of the first openings 130a exposes both the gate structures 112P and 112N. In the illustrated cross-sectional views represented by FIGS. 8C-8D, one of the second openings 130b exposes the gate structure 116N, and another one of the second openings exposes the gate structure 116P. The first and second openings 130a-130b may also expose portions of the ILD layer 128 disposed laterally adjacent to the gate structures 112, 114, 116, 118. Although not shown, as indicated by the top, planar view of the IC structure 20 shown in FIG. 16, the patterned hard mask 130 also includes other openings configured to expose other portions of the gate structures 112, 114, 116, and 118 to facilitate the formation of gate isolation structures (e.g., the gate isolation structures 160) in the SRAM array 100 and of gate isolation structures (e.g., the gate isolation structures 170) in the logic array 200. After patterning the hard mask 130, the patterned masking element 132 is selectively removed.

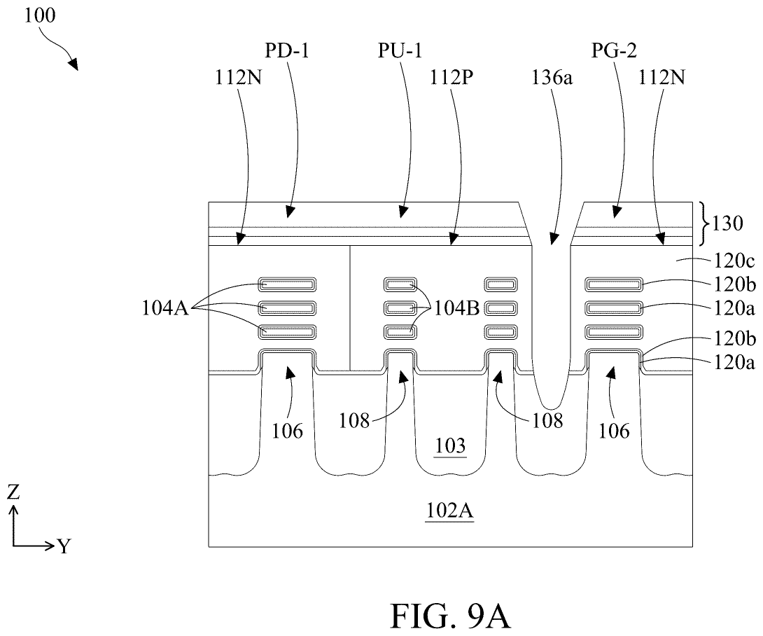

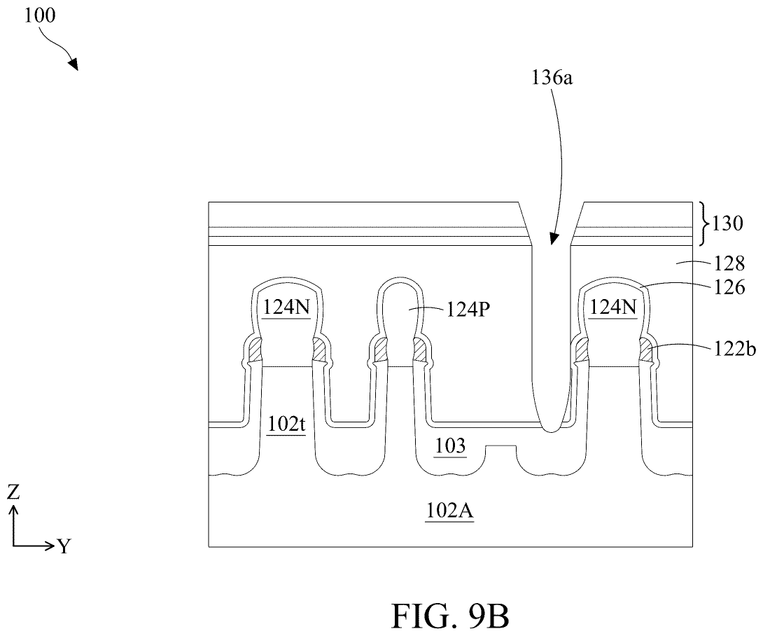

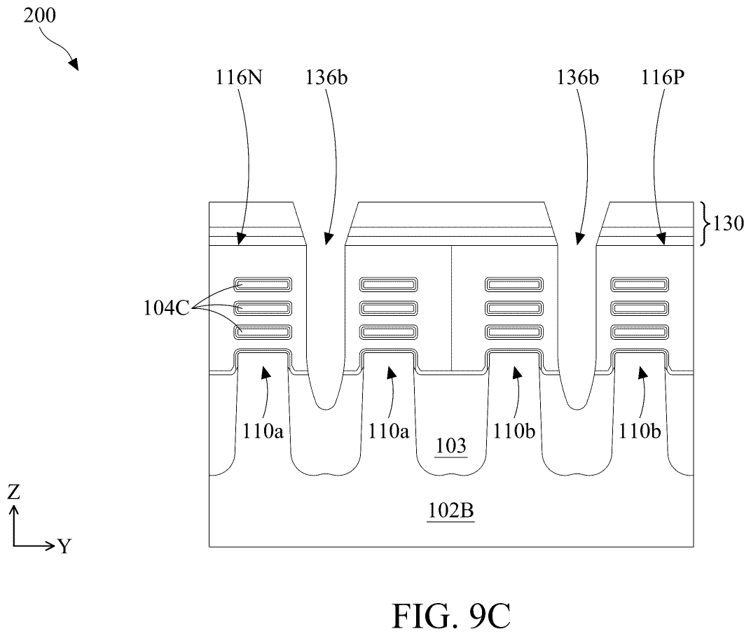

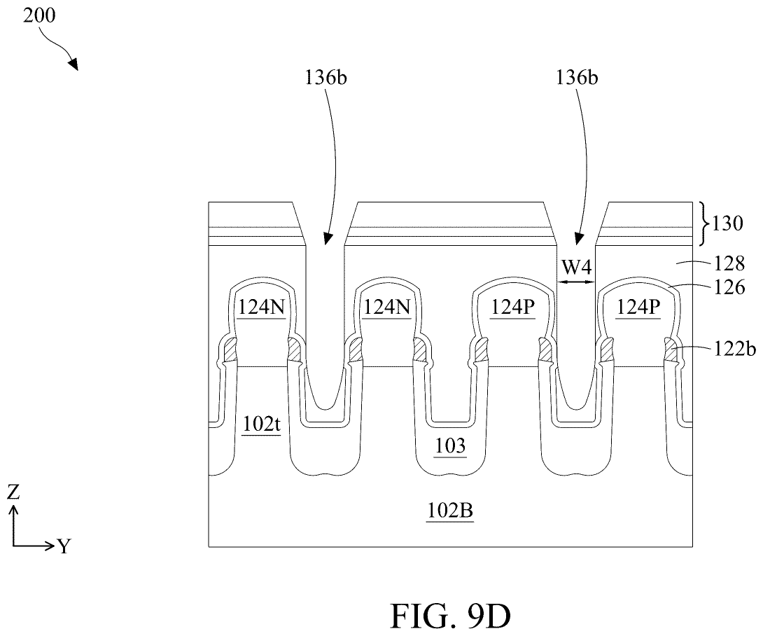

Referring now to FIGS. 4 and 9A-9D, method 400 includes a block 408 where first gate isolation trenches 136a are formed over the first region 102A and second gate isolation trenches 136b are formed over the second region 102B to separate one or more of the exposed gate structures. While using the patterned hard mask 130 as an etch mask, an etching process is performed to the IC structure 10 to form the first gate isolation trenches 136a in the SRAM array 100 over the first region 102A and the second gate isolation trenches 136b in the logic array 200 over the second region 102B. In some implementations, the etching process may be a dry etching process. An exemplary dry etching process may implement an oxygen-containing gas, hydrogen, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. In an embodiment, to form gate isolation trenches with high aspect ratios, the formation of the first and second gate isolation trenches 136a-136b may include performing an atomic layer etching (ALE) process that includes performing a depositing process, performing an etching process after the performing of the depositing process, and repeating the depositing process and etching process for multiple cycles. In embodiments represented by FIG. 9A, the first gate isolation trench 136a extends through the gate structures 112P and 112N and the STI feature 103 thereunder and is disposed between the active region 106 and the active region 108. In embodiments represented by FIG. 9C, one of the second gate isolation trenches 136b extends through the gate structure 116N and into the STI feature 103 and is disposed between two active regions 110a, and another one of the second gate isolation trenches 136b extends through the gate structure 116P and into the STI feature 103 and is disposed between two active regions 110b. The second gate isolation trenches 136b may span a width W4 (shown in FIG. 9D) along the Y direction.

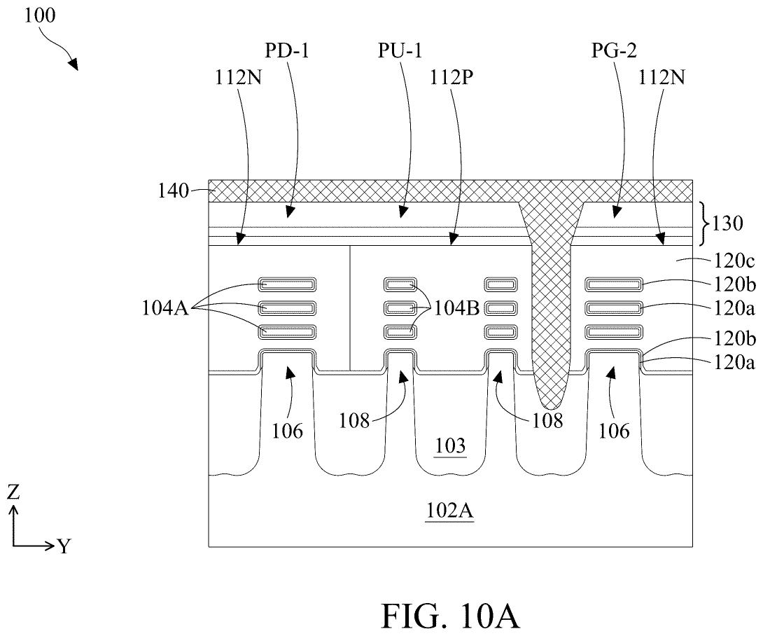

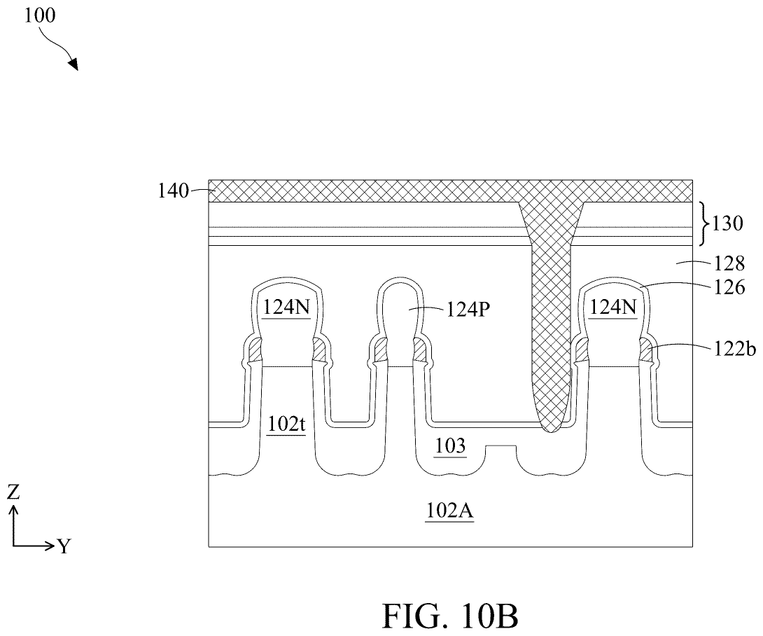

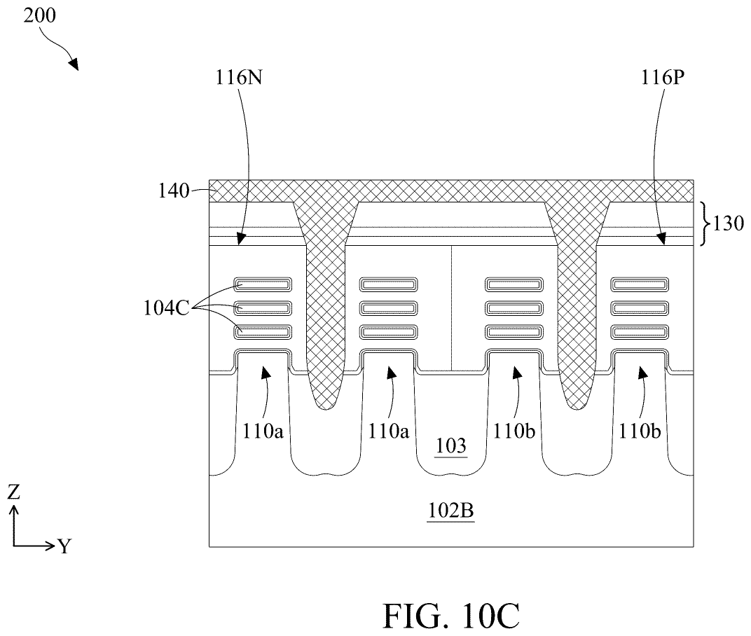

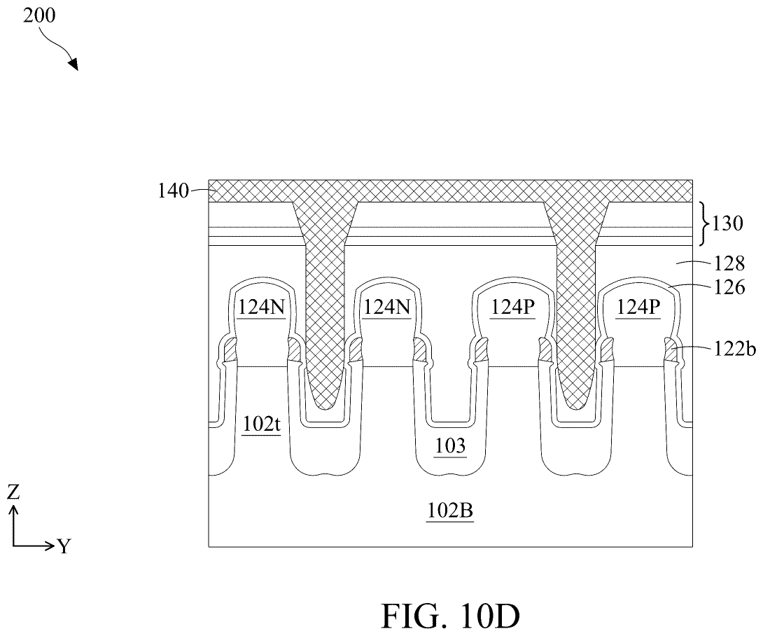

Referring now to FIGS. 4 and 10A-10B, method 400 includes a block 410 where a first dielectric layer 140 is formed to substantially fill the first gate isolation trenches 136a and the second gate isolation trenches 136b. In an embodiment, the first dielectric layer 140 is conformally deposited over the IC structure 10 to substantially fill the first gate isolation trenches 136a and the second gate isolation trenches 136b by using any suitable method including CVD, ALD. In the present embodiments, to substantially eliminate or reduce threshold voltage variation caused by gate isolation structures (i.e., the first gate isolation structures 160) in the SRAM array 100, the first dielectric layer 140 includes a dielectric material that is free of oxygen. For example, the first dielectric layer 140 is a nitrogen-containing dielectric material and may include silicon nitride, silicon carbonitride, or other suitable materials. In another embodiment, the first dielectric layer 140 is a nitrogen-containing dielectric material but also includes oxygen. For example, the first dielectric layer 140 may include silicon oxynitride or silicon oxycarbonitride. After the deposition of the first dielectric layer 140, a planarization process (e.g., chemical mechanical polishing) may be performed to the IC structure 10 to provide a planar top surface.

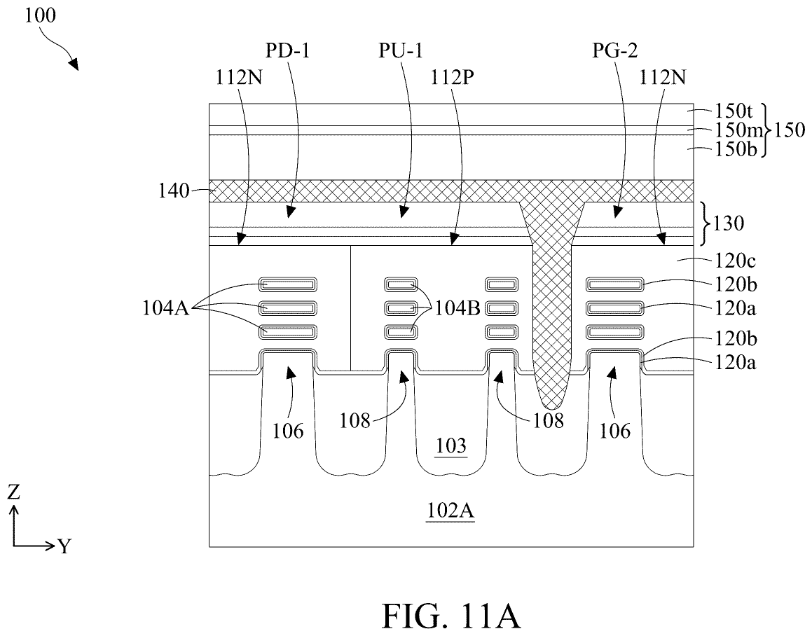

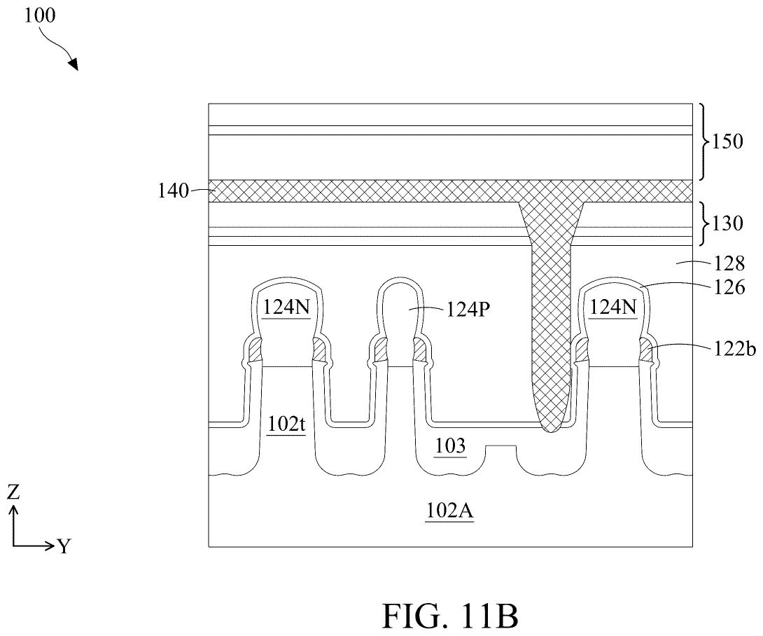

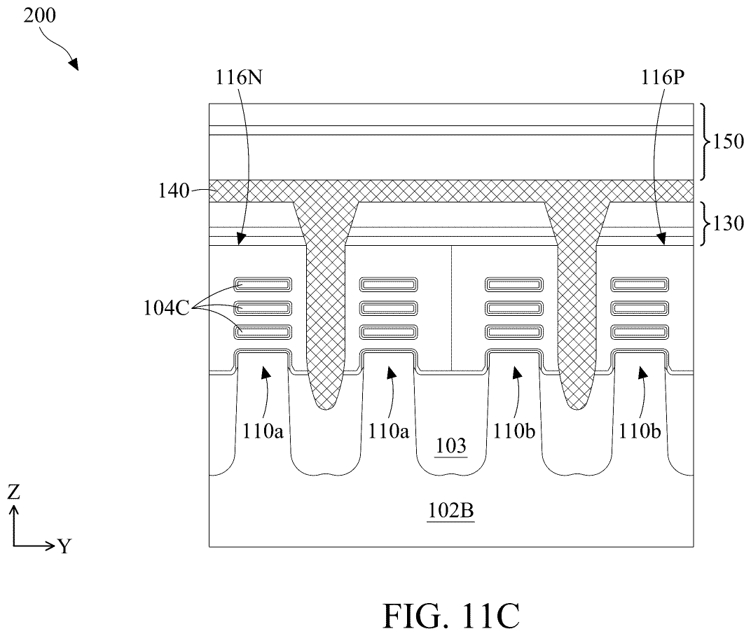

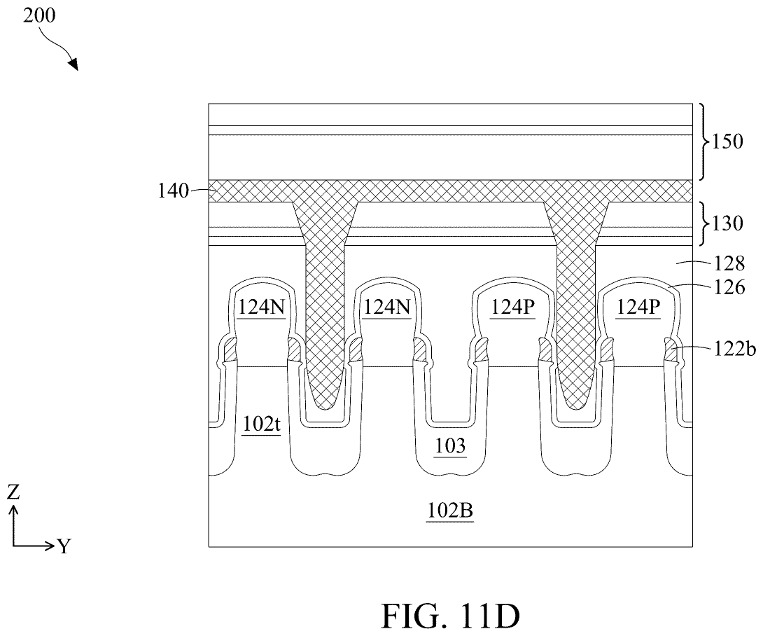

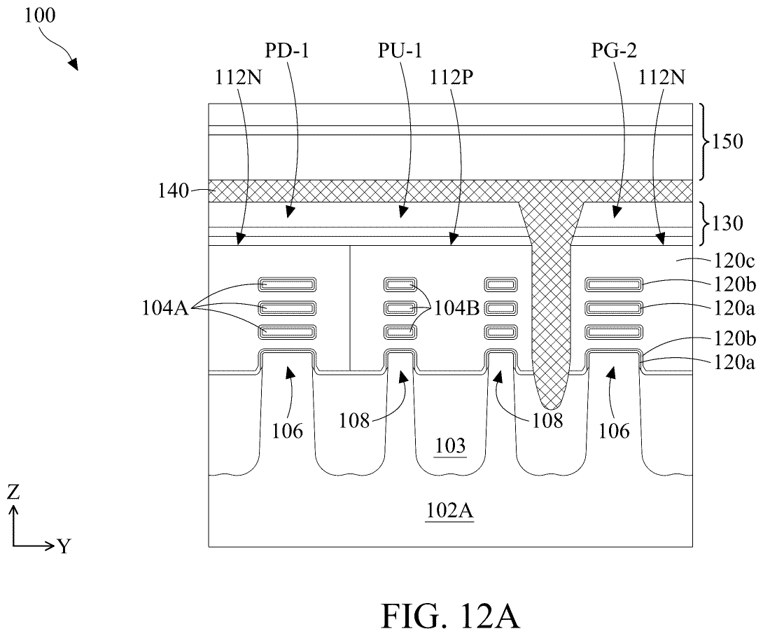

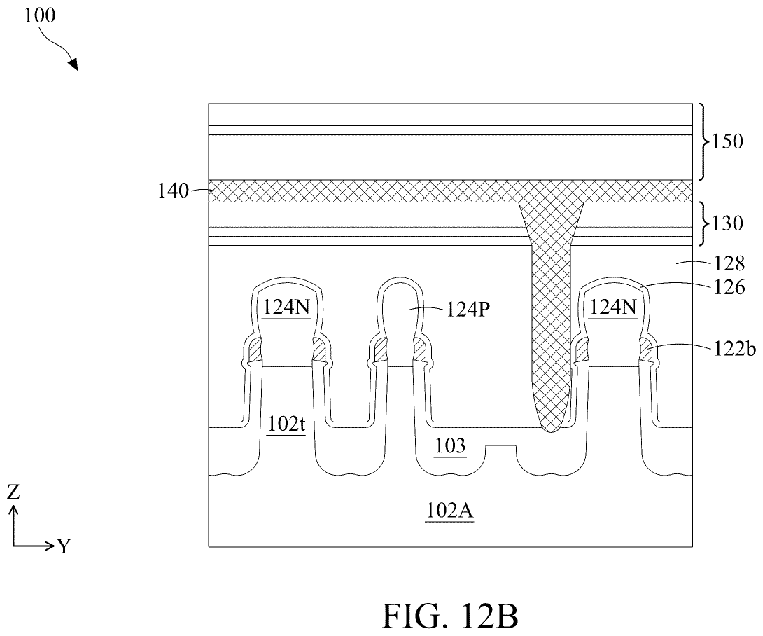

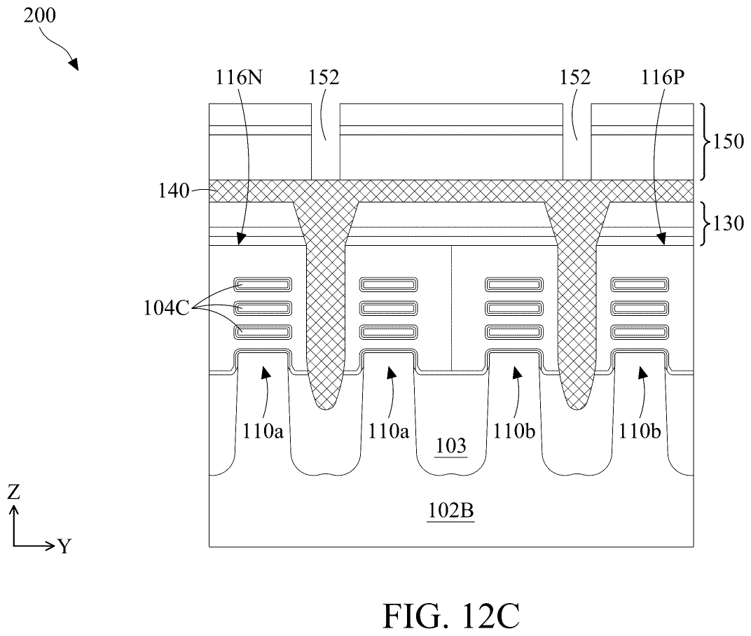

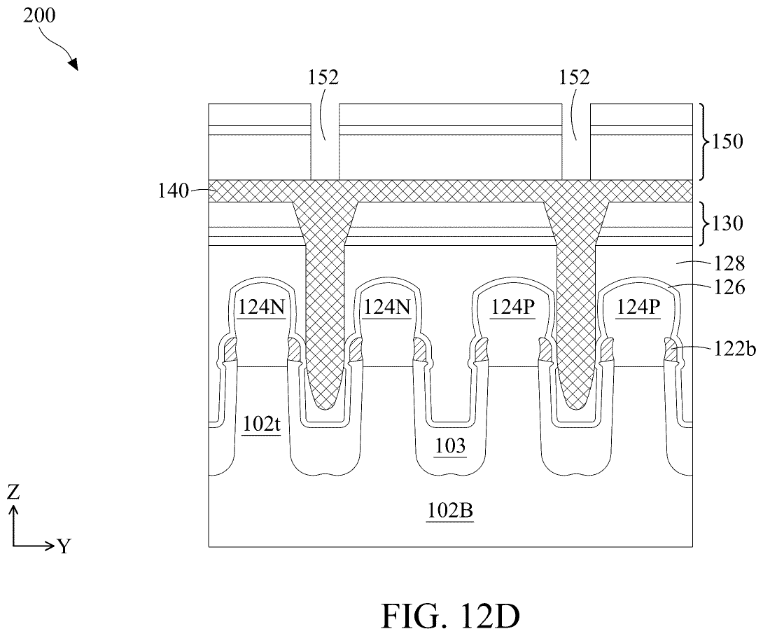

Referring now to FIGS. 4 and 11A-11D and 12A-12D, method 400 includes a block 412 where a patterned resist layer 150 having openings 152 directly over the second gate isolation trenches 136b are formed. With respect to FIGS. 11A-11D, a multi-layer resist layer 150 is formed over the IC structure 10. In an embodiment, the multi-layer resist layer 150 includes a bottom layer 150b, a middle layer 150m deposited over the bottom layer 150b, and a top layer 150t deposited over the middle layer 150m. The bottom layer 150b is a bottom anti-reflective coating (BARC) layer in some embodiments. In an embodiment, the bottom layer 150b is an ashing removal dielectric (ARD) layer. In a further embodiment, the bottom layer 150b is an ARD layer such as amorphous carbon. The middle layer 150m may be an inorganic material. In a further embodiment, the middle layer 150m is a nitride such as silicon nitride, an oxynitride such as silicon oxynitride, or an oxide such as silicon oxide. In an embodiment, the middle layer 150m having an inorganic composition is formed on the bottom layer 150b having an organic composition. The top layer 150t is photosensitive and may include a photoresist in some embodiments. With respect to FIGS. 12A-12D, the top layer 150t is patterned using photolithography techniques (e.g., an extreme ultraviolet (EUV) lithography or 193 nm immersion (193i) photolithography) to form openings, and the middle layer 150m and the bottom layer 150b may be then patterned while using the patterned top layer 150t as an etch mask. As a result of the patterning, the patterned resist layer 150 covers the SRAM array 100 and includes openings 152 over the logic array 200. More specifically, the openings 152 are disposed directly over the second gate isolation trenches 136b over the second region 102B. Although not shown, when viewed from top, the openings 152 extend lengthwise along the X direction.

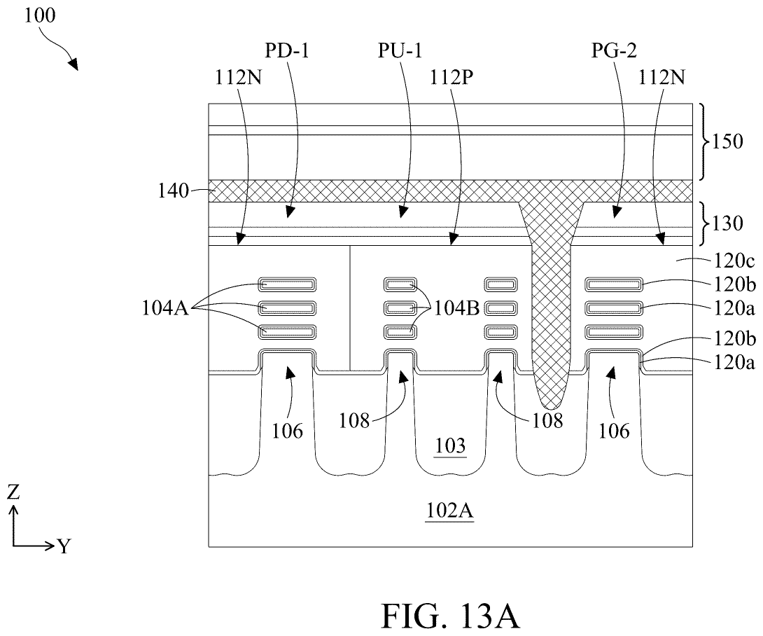

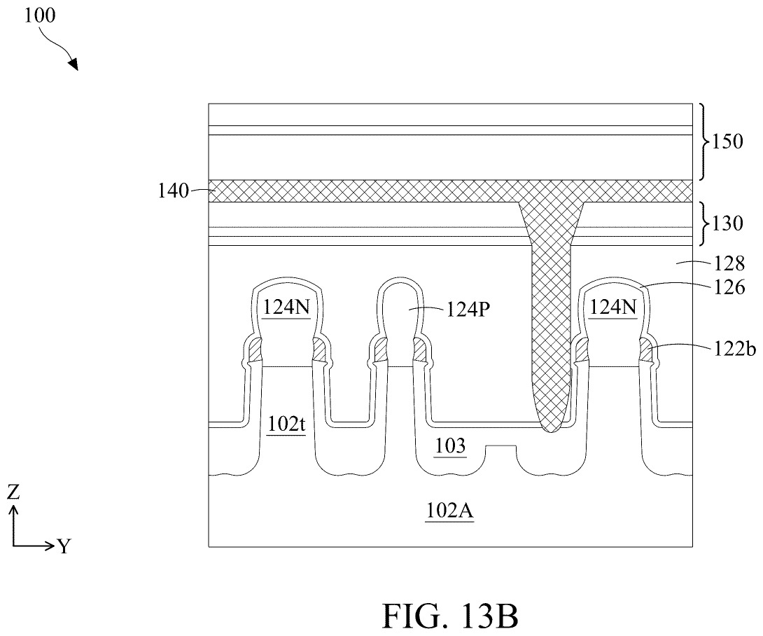

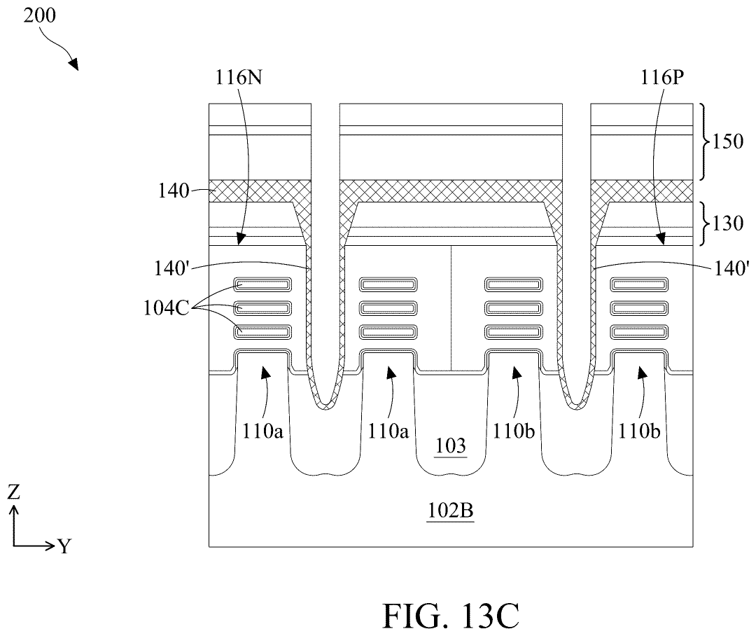

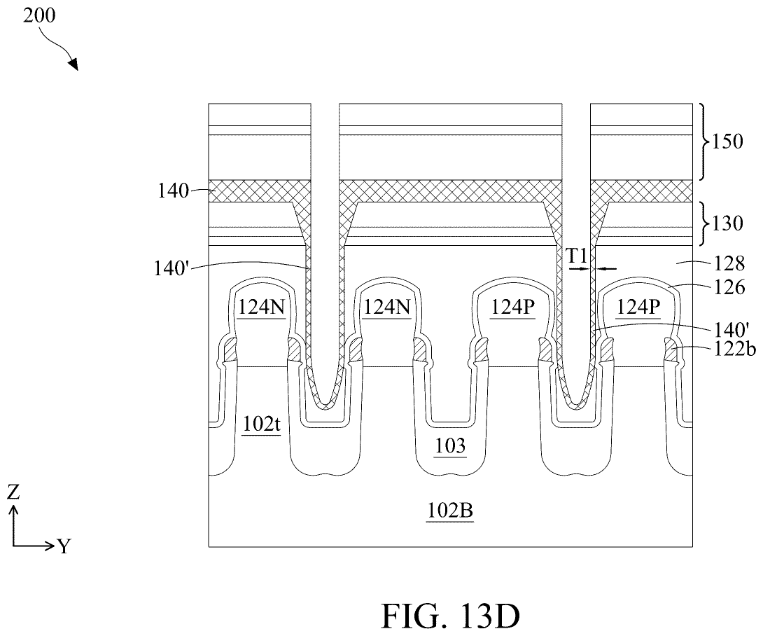

Referring now to FIGS. 4 and 13A-13D, method 400 includes a block 414 where the first dielectric layer 140 is etched back to form dielectric liners 140′ in each of the second gate isolation trenches 136b. While using the patterned resist layer 150 as an etch mask, an etching process is performed to selectively etch the portion of the first dielectric layer 140 exposed by the openings 152 over the second region 102B, thereby forming the dielectric liner 140′ in the second gate isolation trenches 136b. The etching process is a dry etch, a wet etch, other suitable etch, or combinations thereof. In some embodiments, the etchant is a fluorine-based etchant, such as hydrofluoric acid (HF) or a mixture of HF and ammonium fluoride (NH₄F). In some embodiments, fluorine-based etchant is a wet etchant. In an embodiment, a ratio of a thickness T1 of the dielectric liner 140′ to the width W4 of the second gate isolation trench 136b may be no more than about 10%. For example, the ratio is no more than about 5% and is greater than 0. If the first dielectric layer 140 is fully removed from the second gate isolation trenches 136b, the source/drain features disposed adjacent to the second gate isolation trenches 136b may be damaged, adversely affecting the device performance; if the ratio is greater than 10%, the difficulty for forming the patterned resist layer 150 with small opening sizes will be increased, and the reduction to the parasitic capacitance associated with the dielectric liner 140′ may be not good enough. In an embodiment, the thickness T3 is greater than 0 nm and no greater than about 3 nm (e.g., 0 nm<T3<3 nm). In an embodiment, the thickness T1 of the dielectric liner 140′ is not uniform within the second gate isolation trench 136b. After the etch back of the first dielectric layer 140 over the second region 102B, the patterned resist layer 150 may be selectively removed.

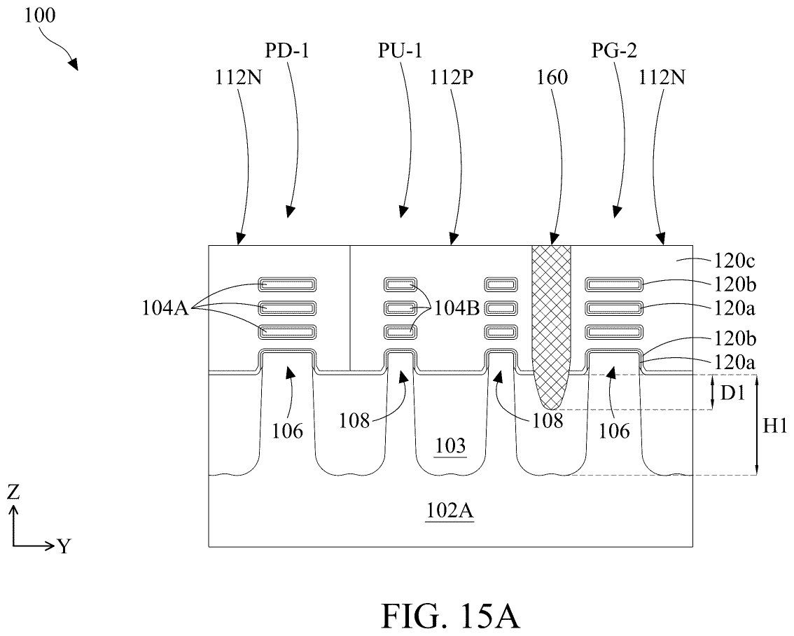

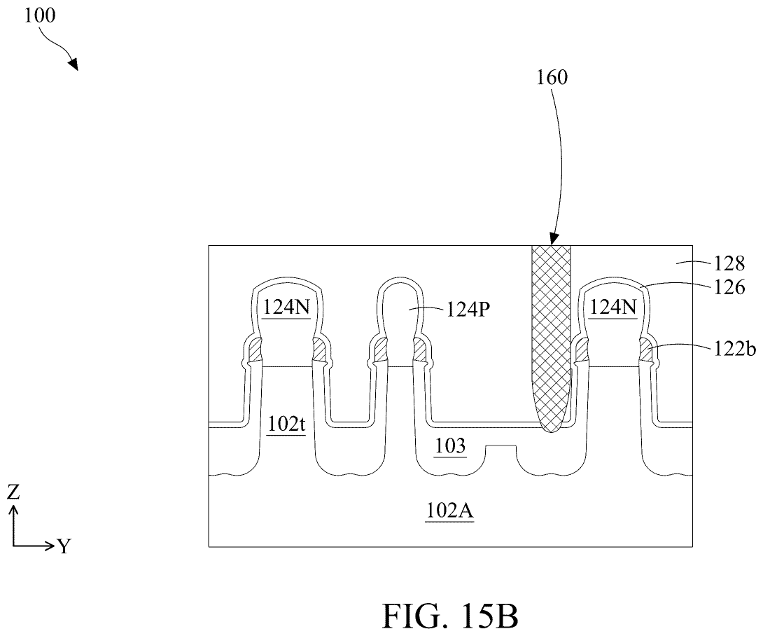

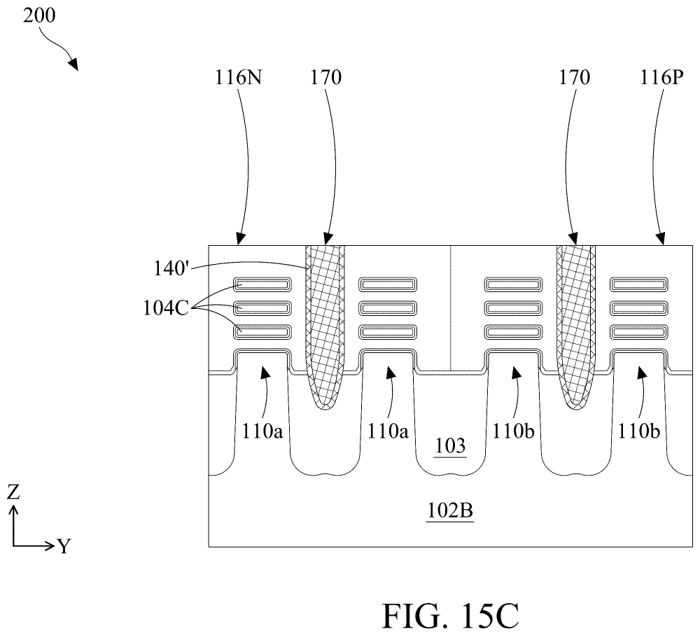

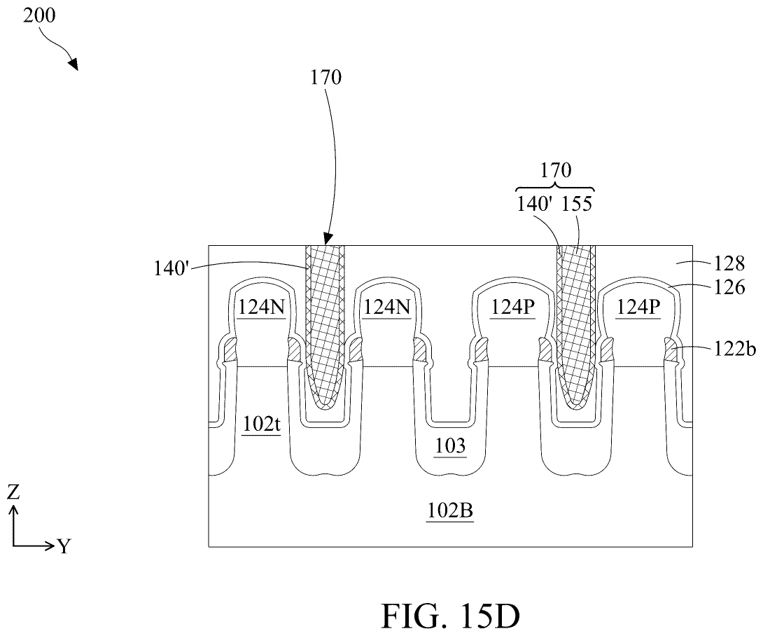

Referring now to FIGS. 4 and 15A-15D, method 400 includes a block 416 where a second dielectric layer 155 is formed over the dielectric liner 140′ to substantially fill the second gate isolation trenches 136b. After the etch back of the first dielectric layer 140, the second dielectric layer 155 is deposited over the IC structure 10 to fill the remaining portion of second gate isolation trenches 136b. In an embodiment, the second dielectric layer 155 may be conformally or non-conformally deposited over the substrate 202. In an embodiment, to reduce parasitic capacitance between two conductive features, the second dielectric layer 155 may include silicon oxide, low-k dielectric material, or a combination thereof. The low-k dielectric material may include porous silicon oxide, doped silicon oxide (e.g., SiOC, BPSG, FSG, PSG, BSG, etc.), other low-k dielectric materials, or combinations thereof, and may be formed by any suitable method including CVD, ALD. Notably, the composition of the second dielectric layer 155 is distinctly different from that of the first dielectric layer 140. In an embodiment, a dielectric constant of the first dielectric layer 140 is greater than a dielectric constant of the second dielectric layer 155. In an embodiment, the first dielectric layer 140 is free of oxygen, and the second dielectric layer 155 is free of nitrogen. In another embodiment, the first dielectric layer 140 includes oxygen, and an oxygen concentration of the first dielectric layer 140 is less than oxygen concentration of the second dielectric layer 155. In one embodiment, the first dielectric layer 140 includes silicon nitride, the second dielectric layer 155 includes silicon oxide. In another embodiment, the first dielectric layer 140 includes silicon oxynitride, the second dielectric layer 155 includes silicon oxide.

After the deposition of the second dielectric layer 155, a planarization process (e.g., one or more chemical mechanical polishing) may be performed to remove excess portions of the first dielectric layer 140 and the second dielectric layer 155 until a top surface of the gate electrode 120c is exposed, thereby defining final structures of first gate isolation structures 160 formed in the first gate isolation trenches 136a and second gate isolation structures 170 formed in the second gate isolation trenches. More specifically, the SRAM array 100 includes first gate isolation structures 160 formed of the first dielectric layer 140, and the logic array 200 includes second gate isolation structures 170 formed of two layers: the second dielectric layer 155 and the dielectric liner 140′ extending along sidewalls and bottom surface of the second dielectric layer 155. The dielectric liner 140′ is formed by etching the first dielectric layer 140 and thus have the same composition as that of the first dielectric layer 140. In some embodiments, during the deposition of the first dielectric layer 140, one or more seams (e.g., air gaps) may be formed in the first gate isolation trenches 136a and/or the second gate isolation trenches 136b. As a result, the first gate isolation structures 160 may include seams, while the second gate isolation structures 170 may not include seams due to the etch back of the first dielectric layer 140. In the cross-sectional view represented by FIG. 15A, the protrusion 102t has lower portion disposed laterally adjacent to the isolation feature 103 and an upper portion over the isolation features 103. The upper portion 102t of the protrusion 102t has a height H1. The first gate isolation structure 160 extends into the isolation feature 103. That is, a distance D1 between the top surface of the isolation feature 103 and the bottom surface of the first gate isolation structure 160 is greater than 0. In an embodiment, a ratio of the distance D1 to the height H1 (i.e., D1/H1) is less than ⅓. In another embodiment, the ratio of the distance D1 to the height H1 (i.e., D1/H1) is in a range between about ⅓ and about ⅔.

In an embodiment, one of the first gate isolation structure 160 in the SRAM array 100 is in direct contact with a gate structure (e.g., gate structure 112N) of an N-type transistor and a gate structure (e.g., gate structure 112P) of a P-type transistor. The gate structures of N-type transistor and P-type transistor may have different numbers of layers and may include different materials (e.g., N-type work function layer, P-type work function layer). That is, opposite sides of the first gate isolation structure 160 may contact different numbers of layers and different materials.

Method 400 may also include performing further processes. Such further processes may include forming device-level contacts, such as gate contacts (not depicted) formed over the segments of gate structures, source/drain contacts formed over source/drain features, butted contacts. Such further processes may also include forming a multi-layer interconnect (MLI) structure (not depicted) over the IC structure 10. The MLI may include various interconnect features, such as vias and conductive lines, disposed in dielectric layers, such as etch-stop layers and ILD layers. In some embodiments, the vias are vertical interconnect features configured to interconnect device-level contacts.

FIG. 16 depicts a fragmentary top, plan view of the IC structure 10 after forming the first gate isolation structures 160 in the SRAM array 100 and the second gate isolation structures 170 in the logic array 200. In embodiments represented in FIG. 16, for each SRAM cell 101 in the SRAM array 100, each gate structure (e.g., 112, 114) is separated or cut into two electrically and physically isolated segments. For example, in the lower left SRAM cell 101, the gate structure 112 is cut by one of the first gate isolation structures 160 into segments 112N and 112P such that a gate electrode of the pass-gate transistor PG-2 is electrically isolated from gate electrodes of the pull-up transistor PU-1 and pull-down transistor PD-1. Similarly, in the lower left SRAM cell 101 in the SRAM array 100, the gate structure 114 is cut by one of the first gate isolation structures 160 into two segments 114N and 114P such that gate electrode of the pass-gate transistor PG-1 is electrically isolated from gate electrodes of the pull-up transistor PU-2 and pull-down transistor PD-2. Still referring to FIG. 16, some of the first gate isolation structures 160 are configured to provide gate isolation between two adjacent SRAM cells 101. For example, another one of the first gate isolation structures 160 isolates a gate electrode of the pull-down transistor PD-2 in the lower left SRAM cell 101 from a gate electrode of the pull-down transistor PD-2 in the upper left SRAM cell 101. Each of the first gate isolation structures 160 extends lengthwise along the X direction. By forming the first gate isolation structures 160 that are free or oxygen or having a low oxygen concentration, the SRAM array 100 and its SRAM cells 101 may work properly to fulfill desired functions with improved performance.

For the logic array 200, at least one or more of the gate structures (e.g., 116, 118) are cut into two or more electrically and physically isolated segments. For example, in this illustrated embodiment, one of the second gate isolation structures 170 cuts the gate structure 116N into two segments and further cuts the gate structure 118N into two segments; another one of the second gate isolation structures 170 cuts the gate structure 116P into two segments and further cuts the gate structure 118P into two segments. Each of the second gate isolation structures 170 extends lengthwise along the X direction. By forming the second gate isolation structures 170, the logic array 200 and its cells may work properly to fulfill desired functions with improved performance. As described above, by forming gate isolation structures with different configurations in the SRAM array 100 and the logic array 200, both performance (e.g., threshold voltage variation) of the SRAM array and performance (e.g., ring oscillator speed) of the logic array 200 can be improved. In an embodiment, one of the first gate isolation structure 160 in the SRAM array 100 is in direct contact with a gate structure (e.g., gate structure 112N) including a first N-type work function layer, one of the second gate isolation structure 170 in the logic array 200 is in direct contact with another gate structure (e.g., gate structure 116N) including a second N-type work function layer. The first N-type work function layer and the second N-type work function layer may include a same material or different materials. For example, both the first N-type work function layer and the second N-type work function layer include a same aluminum-containing material (e.g., TiAIC or TiAl). Due to the different configurations of the first gate isolation structure 160 and the second gate isolation structure 170, the extent at which oxygen may diffuse into the first N-type work function layer in the SRAM array 100 may be less than the extent at which oxygen may diffuse into the second N-type work function layer in the logic array 200. As a result, oxygen concentration of the first N-type work function layer may be less than oxygen concentration of the second N-type work function layer. In other words, the SRAM array 100 may have less TiAl oxidation compound than that in the logic array 200.

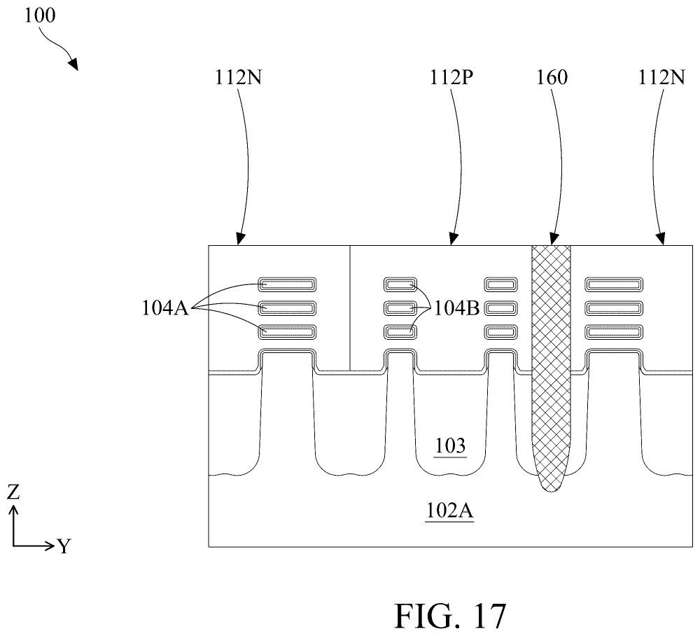

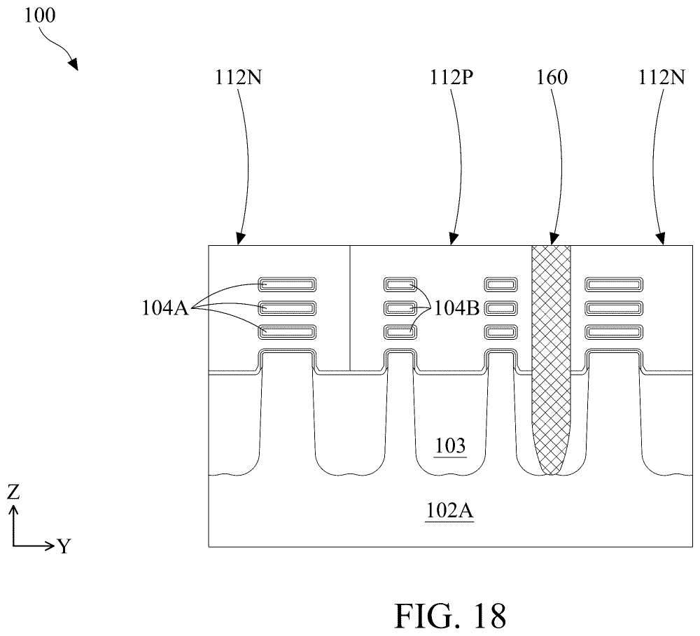

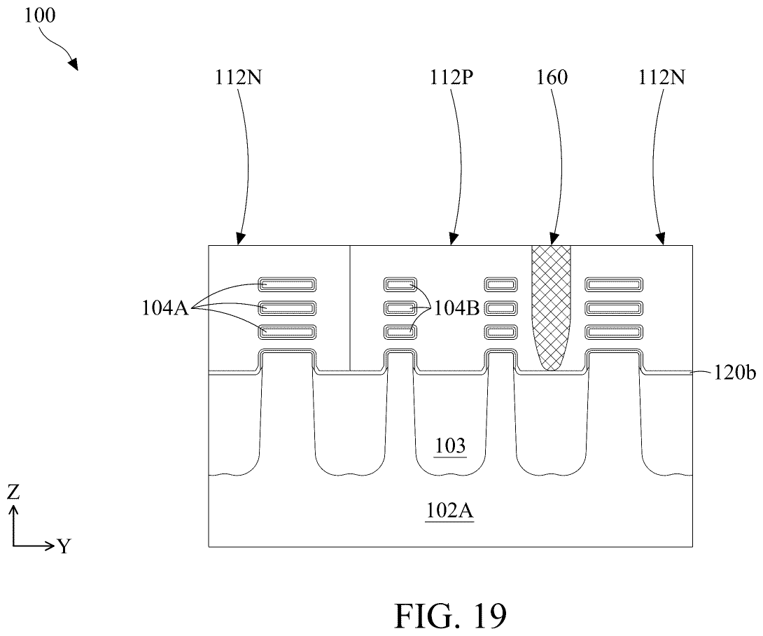

In the above embodiments represented by FIG. 15A, the first gate isolation structure 160 extends through both the gate structure 112P and the gate structure 112N and further extends into the isolation feature 103 thereunder. In various embodiments represented by FIGS. 17, 18, 19, the depth of the first gate isolation structure 160 may be adjusted as long as it can provide satisfactory electrical isolation between the gate structure 112P and the gate structure 112N. For example, with reference to FIG. 17, the first gate isolation structure 160 may further extend through the isolation feature 103 and extend into the substrate 102. In another embodiment represented by FIG. 18, the first gate isolation structure 160 may extend through the isolation feature 103 and terminate on the bottom surface of the isolation feature 103. In another embodiment represented by FIG. 19, the first gate isolation structure 160 may extend through the gate electrodes of the gate structure 112P and the gate structure 112N and terminate on the high-k dielectric layer 120b. Similarly, although not shown, the depth of the second gate isolation structure 170 may be adjusted as long as it can provide satisfactory electrical isolation between different segments of the gate structures or different structures.

In the above embodiments, the first and second gate isolation structures 160 and 170 are formed after the formation of the metal gate structures 112, 114, 116, 118. Those gate isolation structures formed after the formation of the metal gate structures may be referred to as cut-metal-gate (CMG) gate isolation structures. Each CMG gate isolation structure may interface with each layer (e.g., interfacial layer 120a, high-k dielectric layer 120b, multiple layers, such as work function layers, of the gate electrode 120c) of the corresponding metal gate structure (e.g., metal gate structure 112, 114, 116, or 118). As described above, a gate replacement process (or gate-last process) may be adopted where some dummy gate stacks (not shown) serve as placeholders for those functional gate structures 112, 114, 116 and 118. The first and second gate isolation structures 160 and 170 may be formed after the forming of the dummy gate stacks and before the forming of the metal gate structures 112, 114, 116, 118. Those gate isolation structures formed prior to the formation of the metal gate structures may be referred to as cut-poly gate isolation structures. Each cut-poly gate isolation structure may interface with the gate dielectric layer (e.g., interfacial layer 120a, high-k dielectric layer 120b) and space apart from, for example, work function layers of the gate electrode 120c by the gate dielectric layer.

Although not intended to be limiting, one or more embodiments of the present disclosure provide many benefits to an IC structure and the formation thereof. For example, the present embodiments provide an IC structure including first gate isolation structures in the array of memory cells and second gate isolation structures in the array of logic cells. The first and second gate isolation structures are different in terms of composition. In an embodiment, the first gate isolation structures include a nitride-containing dielectric material, and the second gate isolation structures include a two-layer structure having a liner extending along sidewall and bottom surface of a low-k dielectric material, and the liner is formed of the nitride-containing dielectric material. In an embodiment, the nitride-containing dielectric material is an oxygen-free dielectric material. By forming hybrid gate isolation structures in the IC structure, both performance (e.g., threshold voltage variation) of the memory array and performance (e.g., ring oscillator speed) of the logic array can be improved.

The present disclosure provides for many different embodiments. Semiconductor structures and methods of fabrication thereof are disclosed herein. In one exemplary aspect, the present disclosure is directed to a method. The method includes forming a first transistor and a second transistor over a first region of a substrate, forming a third transistor and a fourth transistor over a second region of the substrate, forming a patterned mask over the substrate, the patterned mask comprising a first opening over the first region of the substrate and a second opening over the second region of the substrate, the first opening partially exposing a gate structure of the first transistor and a gate structure of the second transistor, the second opening partially exposing a gate structure of the third transistor and a gate structure of the fourth transistor, performing an etching process to the partially exposed gate structures, thereby forming a first trench over the first region of the substrate and a second trench over the second region of the substrate, depositing a nitrogen-containing layer over the substrate, the nitrogen-containing layer comprising a first portion substantially filling the first trench and a second portion substantially filling the second trench, etching back the second portion of the nitrogen-containing layer without substantially affecting the first portion of the nitrogen-containing layer, and after the etching back of the second portion of the nitrogen-containing layer, forming a low-k dielectric layer in the second trench. In some embodiments, an oxygen concentration of the nitrogen-containing layer is less than an oxygen concentration of the low-k dielectric layer. In some embodiments, the nitrogen-containing layer may include silicon nitride, silicon oxynitride, silicon carbonitride, or silicon oxycarbonitride. In some embodiments, the etching back the second portion of the nitrogen-containing layer may include, after the depositing of the nitrogen-containing layer, forming a patterned resist layer over the substrate, the patterned resist layer covering the first portion of the nitrogen-containing layer and comprising an opening disposed directly over the second portion of the nitrogen-containing layer, performing an etching process to reduce a thickness of the second portion of the nitrogen-containing layer, and selectively removing the patterned resist layer. In some embodiments, the second trench spans a first width, after the etching back of the second portion of the nitrogen-containing layer, the second portion of the nitrogen-containing layer has a first thickness, a ratio of the first thickness to the first width is less than 10%. In some embodiments, the first thickness is no greater than 3 nm. In some embodiments, the first transistor and the second transistor are portions of a memory cell. In some embodiments, the first transistor may include first vertically stacked nanostructures, the second transistor may include second vertically stacked nanostructures, and a width of the first vertically stacked nanostructures is greater than a width of the second vertically stacked nanostructures. In some embodiments, the gate structures extend lengthwise along a first direction, and the first trench and second trench each extend lengthwise along a second direction substantially perpendicular to the first direction.

In another exemplary aspect, the present disclosure is directed to a method. The method includes forming a high-k metal gate structure extending lengthwise along a first direction, forming a trench to separate the high-k metal gate structure into two portions, conformally depositing a first dielectric layer to substantially fill the trench, after the conformally depositing of the first dielectric layer, forming a patterned mask over the high-k metal gate structure, the patterned mask comprising an opening disposed over the trench, etching back the first dielectric layer while using the patterned mask as an etch mask to obtain a thinned first dielectric layer, and after the etching of the first dielectric layer, forming a second dielectric layer in the trench and on the thinned first dielectric layer.

In some embodiments, a dielectric constant of the second dielectric layer is less than a dielectric constant of the first dielectric layer. In some embodiments, the first dielectric layer may include silicon nitride, and the second dielectric layer may include silicon oxide. In some embodiments, the high-k metal gate structure is a first high-k metal gate structure, the trench is a first trench, and the method may also include forming a second high-k metal gate structure, and forming a second trench to separate the second high-k metal gate structure into two portions, wherein the conformally depositing of the first dielectric layer further substantially fills the second trench, and the patterned mask covers the second trench. In some embodiments, the method may also include, before the forming of the high-k metal gate structure, forming an isolation feature over a substrate. A portion of the high-k metal gate structure is over and in direct contact with the isolation feature, and the trench extends through the high-k metal gate structure and extends into the isolation feature. In some embodiments, the trench spans a first width, the thinned first dielectric layer has a first thickness in the trench, and a ratio of the first thickness to the first width is less than about 5%.

In yet another exemplary aspect, the present disclosure is directed to a semiconductor structure. The semiconductor structure includes a memory cell comprising a first transistor and a second transistor, a logic cell comprising a third transistor and a fourth transistor, a first gate isolation structure providing isolation between gate structures of the first transistor and the second transistor, a second gate isolation structure providing isolation between gate structures of the third transistor and the fourth transistor, where an oxygen concentration of the first gate isolation structure is less than an oxygen concentration of the second gate isolation structure.

In some embodiments, the gate structure of the first transistor may include a first aluminum-containing work function layer, the gate structure of the third transistor may include a second aluminum-containing work function layer, and an oxygen concentration of the first aluminum-containing work function layer is less than an oxygen concentration of the second aluminum-containing work function layer. In some embodiments, the first gate isolation structure is formed of a first dielectric material, the second gate isolation structure may include a dielectric liner extending along sidewall and bottom surface of a dielectric filler, and the dielectric liner is formed of the first dielectric material, the dielectric filler is formed of a second dielectric material different than the first dielectric material. In some embodiments, the first dielectric material is free of oxygen, and the second dielectric material is free of nitrogen. In some embodiments, a ratio of a thickness of the dielectric liner to a width of the second gate isolation structure is less than about 10%.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first transistor and a second transistor over a first region of a substrate;
forming a third transistor and a fourth transistor over a second region of the substrate;
forming a patterned mask over the substrate, the patterned mask comprising a first opening over the first region of the substrate and a second opening over the second region of the substrate, the first opening partially exposing a gate structure of the first transistor and a gate structure of the second transistor, the second opening partially exposing a gate structure of the third transistor and a gate structure of the fourth transistor;
performing an etching process to the partially exposed gate structures, thereby forming a first trench over the first region of the substrate and a second trench over the second region of the substrate;
depositing a nitrogen-containing layer over the substrate, the nitrogen-containing layer comprising a first portion substantially filling the first trench and a second portion substantially filling the second trench;
etching back the second portion of the nitrogen-containing layer without substantially affecting the first portion of the nitrogen-containing layer; and
after the etching back of the second portion of the nitrogen-containing layer, forming a low-k dielectric layer in the second trench.

2. The method of claim 1, wherein an oxygen concentration of the nitrogen-containing layer is less than an oxygen concentration of the low-k dielectric layer.

3. The method of claim 1, wherein the nitrogen-containing layer comprises silicon nitride, silicon oxynitride, silicon carbonitride, or silicon oxycarbonitride.

4. The method of claim 1, wherein the etching back the second portion of the nitrogen-containing layer comprises:
after the depositing of the nitrogen-containing layer, forming a patterned resist layer over the substrate, the patterned resist layer covering the first portion of the nitrogen-containing layer and comprising an opening disposed directly over the second portion of the nitrogen-containing layer;
performing an etching process to reduce a thickness of the second portion of the nitrogen-containing layer; and
selectively removing the patterned resist layer.

5. The method of claim 1, wherein the second trench spans a first width, after the etching back of the second portion of the nitrogen-containing layer, the second portion of the nitrogen-containing layer has a first thickness, a ratio of the first thickness to the first width is less than 10%.

6. The method of claim 5, wherein the first thickness is no greater than 3 nm.

7. The method of claim 1, wherein the first transistor and the second transistor are portions of a memory cell.

8. The method of claim 7, wherein the first transistor comprises first vertically stacked nanostructures, the second transistor comprises second vertically stacked nanostructures, and a width of the first vertically stacked nanostructures is greater than a width of the second vertically stacked nanostructures.

9. The method of claim 1, wherein the gate structures extend lengthwise along a first direction, and the first trench and second trench each extend lengthwise along a second direction substantially perpendicular to the first direction.

10. A method, comprising:
forming a high-k metal gate structure extending lengthwise along a first direction;
forming a trench to separate the high-k metal gate structure into two portions;
conformally depositing a first dielectric layer to substantially fill the trench;
after the conformally depositing of the first dielectric layer, forming a patterned mask over the high-k metal gate structure, the patterned mask comprising an opening disposed over the trench;
etching back the first dielectric layer while using the patterned mask as an etch mask to obtain a thinned first dielectric layer; and
after the etching of the first dielectric layer, forming a second dielectric layer in the trench and on the thinned first dielectric layer.

11. The method of claim 10, wherein a dielectric constant of the second dielectric layer is less than a dielectric constant of the first dielectric layer.

12. The method of claim 10, wherein the first dielectric layer comprises silicon nitride, and the second dielectric layer comprises silicon oxide.

13. The method of claim 10, wherein the high-k metal gate structure is a first high-k metal gate structure, the trench is a first trench, and the method further comprises:
forming a second high-k metal gate structure; and
forming a second trench to separate the second high-k metal gate structure into two portions, wherein the conformally depositing of the first dielectric layer further substantially fills the second trench, and the patterned mask covers the second trench.

14. The method of claim 10, further comprising:
before the forming of the high-k metal gate structure, forming an isolation feature over a substrate,
wherein a portion of the high-k metal gate structure is over and in direct contact with the isolation feature, and the trench extends through the high-k metal gate structure and extends into the isolation feature.

15. The method of claim 10, wherein the trench spans a first width, the thinned first dielectric layer has a first thickness in the trench, and a ratio of the first thickness to the first width is less than about 5%.

16. A semiconductor structure, comprising:
a memory cell comprising a first transistor and a second transistor;
a logic cell comprising a third transistor and a fourth transistor;
a first gate isolation structure providing isolation between gate structures of the first transistor and the second transistor;
a second gate isolation structure providing isolation between gate structures of the third transistor and the fourth transistor;
wherein an oxygen concentration of the first gate isolation structure is less than an oxygen concentration of the second gate isolation structure.

17. The semiconductor structure of claim 16, wherein the gate structure of the first transistor comprises a first aluminum-containing work function layer, the gate structure of the third transistor comprises a second aluminum-containing work function layer, and an oxygen concentration of the first aluminum-containing work function layer is less than an oxygen concentration of the second aluminum-containing work function layer.

18. The semiconductor structure of claim 16, wherein the first gate isolation structure is formed of a first dielectric material, the second gate isolation structure comprises a dielectric liner extending along sidewall and bottom surface of a dielectric filler, and the dielectric liner is formed of the first dielectric material, the dielectric filler is formed of a second dielectric material different than the first dielectric material.

19. The semiconductor structure of claim 17, wherein the first dielectric material is free of oxygen, and the second dielectric material is free of nitrogen.

20. The semiconductor structure of claim 17, wherein a ratio of a thickness of the dielectric liner to a width of the second gate isolation structure is less than about 10%.
